(19) United States
(12) Patent Application Publication
(10) Pub. No.: US 2025/0294970 A1
(43) Pub. Date: Sep. 18, 2025

(54) LIGHT EMITTING DEVICE, DISPLAY DEVICE, PHOTOELECTRIC CONVERSION DEVICE, ELECTRONIC APPARATUS, ILLUMINATION DEVICE, AND MOVING BODY

(71) Applicant: CANON KABUSHIKI KAISHA, Tokyo (JP)

(72) Inventor: DAISUKE OKABAYASHI, Kanagawa (JP)

(21) Appl. No.: 19/065,467

(22) Filed: Feb. 27, 2025

(30) Foreign Application Priority Data
Mar. 15, 2024 (JP) 2024-041588

(51) Int. Cl. H10K 59/122

(52) U.S. Cl. CPC H10K 59/122

(57) ABSTRACT

Alight emitting device including light emitting elements arranged on a main surface of a substrate is provided. Each of the light emitting elements includes: a first electrode arranged in a concave portion provided in an insulating layer arranged on the main surface; an organic layer arranged so as to cover the insulating layer and the first electrode, and including a light emitting layer and an organic functional layer; and a second electrode arranged so as to cover the organic layer. A groove is provided in a portion of a side wall of the concave portion farther from the main surface than a surface of the first electrode, and a portion of the insulating layer farther from the main surface than the surface of the first electrode does not overlap the first electrode in an orthogonal projection to the main surface.

### BACKGROUND OF THE INVENTION

### Field of the Invention

The present disclosure relates to a light emitting device, a display device, a photoelectric conversion device, an electronic apparatus, an illumination device, and a moving body.

### Description of the Related Art

In a light emitting device using a self-light emitting element such as an organic electroluminescence (EL) element, a structure in which a plurality of light emitting elements share an organic layer including a light emitting element is known. Sharing the organic layer is advantageous in increasing resolution because it is unnecessary to form the organic layer for each light emitting element. On the other hand, current leakage easily occurs between adjacent light emitting elements via the organic layer. The leakage current causes unintended light emission, and reduces the color gamut representing the representation performance of the light emitting device. Japanese Patent Laid-Open No. 2014-232631 describes that a leakage current between light emitting elements is suppressed by providing an overhang in the edge portion of the opening of an insulating layer having the opening for exposing an electrode arranged for each light emitting element.

### SUMMARY OF THE INVENTION

In the arrangement described in Japanese Patent Laid-Open No. 2014-232631, since the overhang covers a part of the electrode, the opening ratio of the light emitting element decreases.

Some embodiments of the present disclosure provide a technique advantageous in improving the opening ratio of a light emitting element.

According to some embodiments, a light emitting device comprising a plurality of light emitting elements arranged on a main surface of a substrate, wherein each of the plurality of light emitting elements includes: a first electrode arranged in a concave portion provided in an insulating layer arranged on the main surface; an organic layer arranged so as to cover the insulating layer and the first electrode, and including a light emitting layer and an organic functional layer arranged between the light emitting layer and the first electrode; and a second electrode arranged so as to cover the organic layer, a groove is provided in a portion of a side wall of the concave portion farther from the main surface than a surface of the first electrode, and a portion of the insulating layer farther from the main surface than the surface of the first electrode does not overlap the first electrode in an orthogonal projection to the main surface, is provided.

Further features of the present invention will become apparent from the following description of exemplary embodiments with reference to the attached drawings.

### BRIEF DESCRIPTION OF THE DRAWINGS

FIG. 1 is a plan view showing an example of the arrangement of a light emitting device according to an embodiment.

FIG. 2 is a sectional view showing an example of the arrangement of a light emitting element of the light emitting device shown in FIG. 1.

FIG. 3 is a sectional view showing the example of the arrangement of the light emitting element of the light emitting device shown in FIG. 1.

FIGS. 4A and 4B are sectional views showing a manufacturing method of the light emitting device shown in FIG. 1.

FIGS. 5A and 5B are sectional views showing the manufacturing method of the light emitting device shown in FIG. 1.

FIGS. 6A and 6B are sectional views showing the manufacturing method of the light emitting device shown in FIG. 1.

FIGS. 7A and 7B are sectional views showing the manufacturing method of the light emitting device shown in FIG. 1.

FIGS. 8A and 8B are sectional views showing the manufacturing method of the light emitting device shown in FIG. 1.

FIG. 9 is a sectional view showing an example of the arrangement of the light emitting element of the light emitting device shown in FIG. 1.

FIGS. 10A and 10B are sectional views showing a manufacturing method of the light emitting device shown in FIG. 1.

FIG. 11 is a sectional view showing the manufacturing method of the light emitting device shown in FIG. 1.

FIG. 12 is a sectional view showing an example of the arrangement of the light emitting element of the light emitting device shown in FIG. 1.

FIG. 13 is a sectional view showing an example of the arrangement of the light emitting element of the light emitting device shown in FIG. 1.

FIG. 14 is a sectional view showing an example of the arrangement of the light emitting element of the light emitting device shown in FIG. 1.

FIGS. 15A and 15B are sectional views showing an example of the arrangement of a pixel of the light emitting device shown in FIG. 1.

FIGS. 16A to 16C are views showing an example of an image forming device using the light emitting device according to the embodiment.

FIG. 17 is a view showing an example of a display device using the light emitting device according to the embodiment.

FIG. 18 is a view showing an example of a photoelectric conversion device using the light emitting device according to the embodiment.

FIG. 19 is a view showing an example of an electronic apparatus using the light emitting device according to the embodiment.

FIGS. 20A and 20B are views each showing an example of a display device using the light emitting device according to the embodiment;

FIG. 21 is a view showing an example of an illumination device using the light emitting device according to the embodiment.

FIG. 22 is a view showing an example of a moving body using the light emitting device according to the embodiment.

FIGS. 23A and 23B are views each showing an example of a wearable device using the light emitting device according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

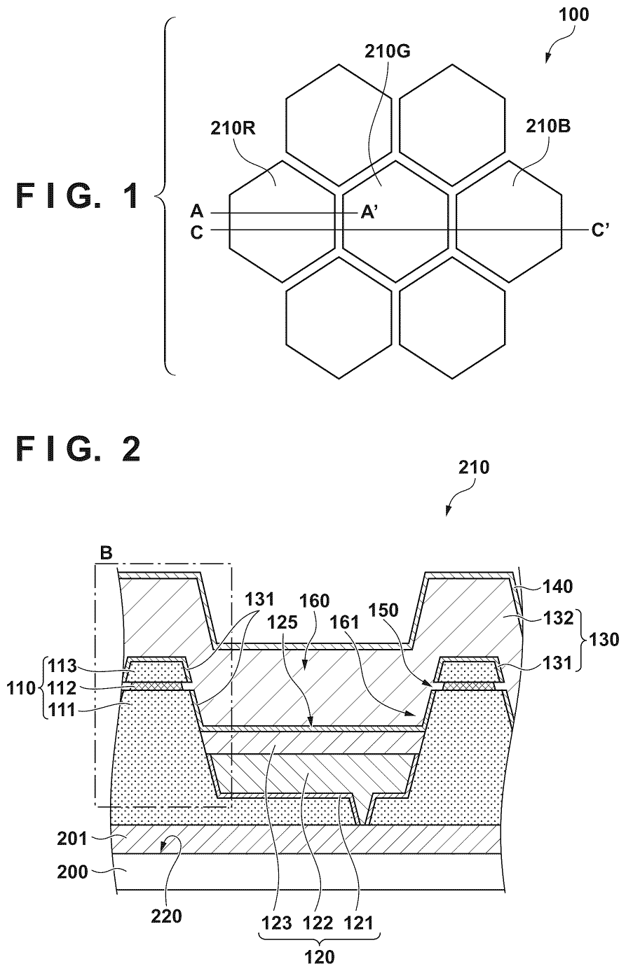

Alight emitting device according to an embodiment of the present disclosure will be described with reference to FIGS. 1 to 15. FIG. 1 is a plan view showing an example of the arrangement of a light emitting device 100 according to this embodiment. FIG. 1 shows a part of the pixel region of the light emitting device 100 where a plurality of light emitting elements 210 are arranged. FIG. 2 is a sectional view taken along a line A-A′ in FIG. 1.

The light emitting device 100 includes a plurality of light emitting elements 210 arranged on a main surface 220 of a substrate 200. As shown in FIG. 1, in this embodiment, the plurality of light emitting elements 210 are arrayed in a delta array, and three adjacent light emitting elements 210R, 210B, and 210G constitute one pixel. “R” of the light emitting element 210R indicates the light emitting element 210 that emits red light. Similarly, “G” of the light emitting element 210G indicates the light emitting element 210 that emits green light, and “B” of the light emitting element 210B indicates the light emitting element 210 that emits blue light. In this specification, when indicating a specific light emitting element 210 among the plurality of light emitting elements 210, a suffix such as “R” of the light emitting element 210R will be added following the reference numeral, and when indicating any of the plurality of light emitting elements 210, it will be simply indicated as the light emitting element “210”. This applies to other components in a similar manner.

In this embodiment, a case of arraying the light emitting elements 210 in the delta array is shown, but the present invention is not limited to this, and another array such as a stripe array or a mosaic array may be used. The light emitting elements 210 of respective colors are described as having the same area, but the area may be varied depending on the light emission color in consideration of the resolution of the light emitting device 100, the light emission efficiency of each color, and the like. Furthermore, as shown in FIG. 1, the shape of the light emitting element 210 is described to have a hexagonal shape, but the shape can be appropriately selected from other shapes such as a rectangular shape.

In this embodiment, an example is described in which three light emitting elements 210 constitute one pixel, but the number of the light emitting elements 210 constituting one pixel is not necessarily three. For example, in accordance with the resolution of the light emitting device 100, the light emission efficiency of each color, and the like, two green light emitting elements 210G may be arranged in one pixel. Alternatively, a light emitting element that emits while light may be arranged in one pixel in addition to the light emitting elements that respectively emit red, blue, and green light components, thereby constituting one pixel by four light emitting elements 210. For example, in a case of the light emitting device 100 configured to perform single color display, one light emitting element 210 may constitute one pixel. Furthermore, the pitch of the light emitting elements 210 adjacent to each other and the pitch of the pixels each constituted by one or more light emitting elements 210 can be arbitrarily set in accordance with the pixel density and the like required for the light emitting device 100.

FIG. 2 schematically shows the sectional structure of one light emitting element 210 perpendicular to the main surface 220 of the substrate 200. Each of the plurality of light emitting elements 210 is provided on a wiring layer 201 arranged on the main surface 220 of the substrate 200. A transistor, a capacitive element, a wiring pattern, and the like are arranged in the substrate 200 and the wiring layer 201. A semiconductor substrate made of silicon or the like can be used for the substrate 200. For the wiring layer 201 where a wiring pattern for connecting the transistor arranged in the substrate 200 and the light emitting element 210, for example, an inorganic material such as silicon oxide (SiOₓ), silicon nitride (SiNₓ), silicon oxynitride (SiON), silicon carbide (SiC), or carbon-containing silicon oxide (SiOC), or an organic material such as acryl or polyimide is used. The light emitting element 210 is arranged on the wiring layer 201 having a planarized surface.

Each of the plurality of light emitting elements includes an electrode 120, an organic layer 130 including a light emitting layer 132 and an organic functional layer 131 arranged between the light emitting layer 132 and the electrode 120, and an electrode 140. The electrode 120 is arranged in a concave portion 160 provided in an insulating layer 110 arranged on the main surface 220 of the substrate 200. The organic layer 130 is arranged so as to cover the insulating layer 110 and the electrode 120 embedded in the concave portion 160 provided in the insulating layer 110. The electrode 140 is arranged so as to cover the organic layer 130.

The insulating layer 110 including the concave portion 160 where the electrode 120 is arranged is arranged on the wiring layer 201. A groove 150 is provided in a portion of a side wall 161 of the concave portion 160 provided in the insulating layer 110, which is farther from the main surface 220 of the substrate 200 than a surface 125 of the electrode 120. For example, in an orthogonal projection to the main surface 220 of the substrate 200, the groove 150 may be arranged so as to surround the electrode 120. A portion of the insulating layer 110 farther from the main surface 220 of the substrate 200 than the surface 125 of the electrode 120 is formed so as not to overlap the electrode 120 in the orthogonal projection to the main surface 220 of the substrate 200.

The insulating layer 110 may be formed using, for example, a chemical vapor deposition (CVD) method, a physical vapor deposition (PVD) method, an atomic layer deposition (ALD) method, a coating method, or the like. For the insulating layer 110, an inorganic material such as silicon oxide, silicon nitride, silicon oxynitride, silicon carbide, carbon-containing silicon oxide, or aluminum oxide, or an organic material such as acryl or polyimide may be used. The concave portion 160 can be patterned into a desirable shape using, for example, a photolithography method, an etching method, and the like. The concave portion 160 provided in the insulating layer 110 is a region surrounded by the side wall 161 and a bottom surface where the electrode 120 is arranged. In the sectional view shown in FIG. 2, a portion including (surrounded by) two side walls 161 and one bottom surface is the concave portion 160. In this embodiment, the insulating layer 110 includes an insulating layer 113, an insulating layer 112 arranged between the insulating layer 113 and the main surface 220 of the substrate 200, and an insulating layer 111 arranged between the insulating layer 112 and the main surface 220 of the substrate 200. In the side wall 161 of the concave portion 160 provided in the insulating layer 110, the above-described groove 150 is formed by the insulating layer 112 recessed more than the insulating layer 111 and the insulating layer 113 in a direction parallel to the main surface 220 of the substrate 200.

The insulating layer 112 can contain a material different from materials for the insulating layer 111 and the insulating layer 113. The insulating layer 111 and the insulating layer 113 may be made of the same material. Alternatively, for example, the insulating layer 111, the insulating layer 112, and the insulating layer 113 may be formed of materials different from each other. Here, the material indicates the above-described silicon oxide, silicon nitride, acryl, polyimide, or the like. The insulating layer 111, the insulating layer 112, and the insulating layer 113 may be formed of materials having different selectivities with respect to the etchant used to form the groove 150. For example, the insulating layer 112 may contain a material having a higher etching rate than the insulating layer 111 and the insulating layer 113 with respect to the etchant used to form the groove 150. In this case, the groove 150 can be formed relatively easily using a manufacturing method to be described later. The etching rates (selectivities) of the insulating layers 111, 112, and 113 can be adjusted by appropriately selecting the materials used for the insulating layers 111, 112, and 113, the etchant, and the like. In this embodiment, the insulating layer 110 is constituted by three layers of the insulating layers 111, 112, and 113, but one or more additional insulating layers may be arranged between the insulating layer 111 and the wiring layer 201.

As described above, the electrode 120 is arranged in the concave portion 160 formed in the insulating layer 110. The electrode 120 is provided so as to be electrically separated for each light emitting element 210. As shown in FIG. 2, the electrode 120 may include a conductive layer 123, a conductive layer 122 arranged between the conductive layer 123 and the main surface 220 of the substrate 200, and a conductive layer 121 arranged between the conductive layer 122 and the main surface 220 of the substrate 200. In this case, for example, the conductive layer 121 may be a barrier metal layer, the conductive layer 122 may be a reflective metal layer, and the conductive layer 123 may be a transparent electrode layer. By arranging the conductive layer 122 functioning as a reflective metal layer to increase the reflectance of light emitted from the light emitting layer 132, the light emission efficiency of the light emitting element 210 can be increased.

For the conductive layer 122, a metal material having a reflectance of 80% or more to the light emission wavelength of the light emitting layer 132 may be used. For the conductive layer 122, a metal such as aluminum or silver, or an alloy thereof added with silicon, copper, nickel, neodymium, or the like may be used. If the conductive layer 122 has a high reflectance to the wavelength of light emitted from the light emitting layer 132, a metal such as titanium, titanium nitride, tantalum nitride, tungsten, molybdenum, gold, or chromium, an alloy thereof, or the like may be used for the conductive layer 121 functioning as a barrier metal layer. The conductive layer 121 may have a stacked structure or a single layer structure. By setting the film thickness of the conductive layer 123, which is a transparent electrode layer, to an appropriate value, the light emission efficiency of the light emitting element 210 can be increased. For the conductive layer 123, a transparent electrode material such as indium tin oxide or indium zinc oxide may be used. The conductive layers 121, 122, and 123 may be formed using, for example, a sputtering method or the like.

The organic layer 130 includes the organic functional layer 131 and the light emitting layer 132. The organic functional layer 131 is arranged between the insulating layer 110 and the light emitting layer 132 and between the electrode 120 and the light emitting layer 132. The organic functional layer 131 may be a hole transport layer. The organic functional layer 131 may be a hole injection layer or an electron blocking layer. The organic functional layer 131 may have a stacked structure of appropriate layers selected from a hole transport layer, a hole injection layer, an electron blocking layer, and the like. The light emitting layer 132 is arranged between the organic functional layer 131 and the electrode 140. The light emitting layer 132 may be formed continuously over the whole pixel region where the plurality of light emitting elements 210 are arranged, and may be shared by the plurality of light emitting elements 210. For the light emitting layer 132, appropriate materials can be selected from the viewpoints of light emission efficiency, operating life, optical interference, and the like. The light emitting layer 132 may have a stacked structure of light emitting layers that emit light components of different colors, or may be a mixed layer obtained by mixing light emitting dopants that emit light components of different colors. Furthermore, an organic functional layer different from the organic functional layer 131 may be arranged between the light emitting layer 132 and the electrode 140. The organic functional layer arranged between the light emitting layer 132 and the electrode 140 may be an electron transport layer, an electron injection layer, a hole blocking layer, or the like, or may have a stacked structure of appropriate layers selected from an electron transport layer, an electron injection layer, a hole blocking layer, and the like.

Here, a region between the light emitting layer and the electrode serving as an anode, which is one of the electrode 120 and the electrode 140, is a hole transport region, and a region between the light emitting layer and the electrode serving as a cathode, which is the other of the electrode 120 and the electrode 140, is an electron transport region. In this embodiment, the electrode 120 is the anode and the electrode 140 is the cathode. However, the present invention is not limited to this, and the electrode 120 may be the cathode and the electrode 140 may be the anode. In that case, the organic functional layer 131 may be an electron transport layer, an electron injection layer, a hole blocking layer, or the like, or may have a stacked structure of appropriate layers selected from an electron transport layer, an electron injection layer, a hole blocking layer, and the like. Similarly, the organic functional layer arranged between the light emitting layer 132 and the electrode 140 may be a hole transport layer, a hole injection layer, an electron blocking layer, or the like, or may have a stacked structure of appropriate layers selected from a hole transport layer, a hole injection layer, an electron blocking layer, and the like. The hole transport region and the electron transport region may be collectively referred to as charge transport regions.

The electrode 140 is arranged on the organic layer 130. Similar to the light emitting layer 132, the electrode 140 may be formed continuously over the whole pixel region where the plurality of light emitting elements 210 are arranged, and may be shared by the plurality of light emitting elements 210. The electrode 140 may be an electrode that transmits at least part of the light reaching the lower surface of the electrode 140. The electrode 140 may function as a semi-transmissive reflective layer that transmits part of light and reflects the other part of the light (that is, semi-transmissive reflectivity). For the electrode 140, for example, a metal such as magnesium or silver, an alloy containing magnesium or silver as a main component, an alloy material containing an alkali metal or an alkaline earth metal, or the like may be used. Similar to the conductive layer 123, an oxide conductor may be used for the electrode 140. The electrode 140 may have a single layer structure or a stacked structure as long as an appropriate transmittance is provided.

The groove 150 is a depression formed in the surface of the side wall 161 of the concave portion 160 provided in the insulating layer 110. As described above, the groove 150 may be a portion where the insulating layer 112 is recessed more than the insulating layer 111 and the insulating layer 113 in the side wall 161 of the concave portion 160 provided in the insulating layer 110. By arranging the groove 150 in the side wall 161, the organic functional layer 131 is divided at the groove 150, or includes a portion covering the groove 150 and having a film thickness smaller than a film thickness of an adjacent portion adjacent to the portion covering the groove 150. That is, when the groove 150 is arranged in the side wall 161 of the concave portion 160 formed in the insulating layer 110, the resistance of the organic functional layer 131 can become high in the groove 150 or in the vicinity of the groove 150. The organic functional layer 131 functioning as a hole transport layer, a hole injection layer, or the like has low resistivity and can become a path for a leakage current between adjacent light emitting elements 210. By increasing the resistance of the organic functional layer 131 between adjacent light emitting elements 210, a leakage current between the light emitting elements 210 can be suppressed.

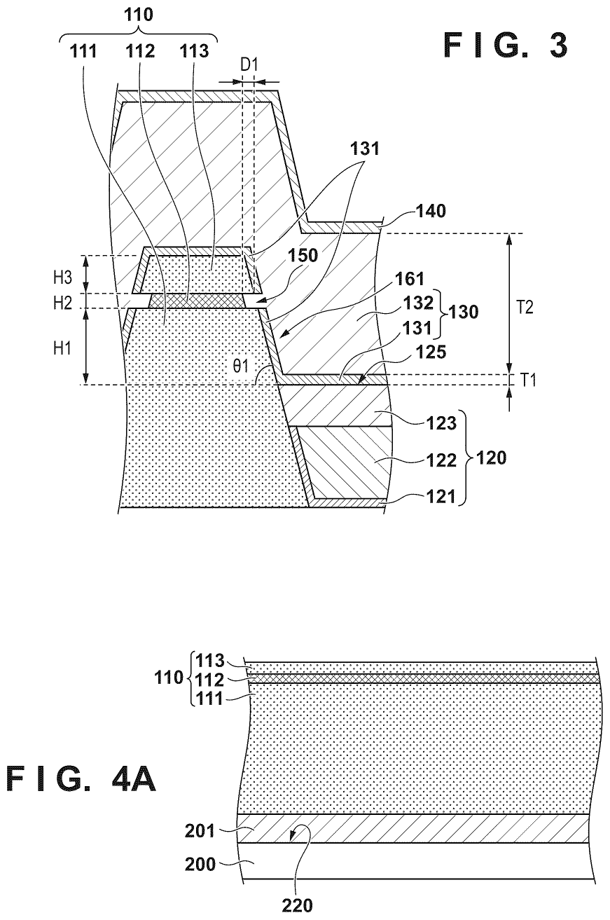

FIG. 3 is an enlarged sectional view of a portion B shown in FIG. 2. As shown in FIG. 3, a length H1 indicates the length between the surface 125 of the electrode 120 and the insulating layer 112 in the normal direction of the main surface 220 of the substrate 200. It can also be said that the length H1 indicates the height of a portion of the insulating layer 111 above the surface 125 of the electrode 120. Similarly, a length H2 indicates the length of the insulating layer 112 in the normal direction of the main surface 220 of the substrate 200. It can also be said that the length H2 indicates the film thickness of the insulating layer 112 in the normal direction of the main surface 220 of the substrate 200. Further, a length H3 indicates the length of the insulating layer 113 in the normal direction of the main surface 220 of the substrate 200. It can also be said that the length H3 indicates the film thickness of the insulating layer 113 in the normal direction of the main surface 220 of the substrate 200.

As shown in FIG. 3, a length T1 indicates the length, in the normal direction of the main surface 220 of the substrate 200, of a portion of the organic functional layer 131 in contact with the electrode 120. It can also be said that the length T1 indicates the film thickness, in the normal direction of the main surface 220 of the substrate 200, of the portion of the organic functional layer 131 in contact with the electrode 120. The length T1 may be the film thickness, in the normal direction of the main surface 220, of the organic functional layer 131 arranged at the geometric centroid position of the electrode 120 in the orthogonal projection to the main surface 220 of the substrate 200. Similarly, a length T2 indicates the length, in the normal direction of the main surface 220 of the substrate 200, of a portion of the organic layer 130 excluding the organic functional layer 131 arranged on the electrode 120. It can also be said that the length T2 indicates the film thickness of the light emitting layer 132 in the normal direction of the main surface 220 of the substrate 200. Further, as described above, if an organic functional layer is further arranged between the light emitting layer 132 and the electrode 140, it can also be said that the length T2 indicates the sum of the film thickness of the light emitting layer 132 and the film thickness of the organic functional layer arranged between the light emitting layer 132 and the electrode 140 in the normal direction of the main surface 220 of the substrate 200. The length T2 may be the film thickness, in the normal direction of the main surface 220, of the organic layer 130 excluding the organic functional layer 131 arranged at the geometric centroid position of the electrode 120 in the orthogonal projection to the main surface 220 of the substrate 200.

Furthermore, as shown in FIG. 3, a length D1 indicates the length of the insulating layer 113 protruding from the insulating layer 112 in the side wall 161 of the concave portion 160 provided in the insulating layer 110. It can also be said that the length D1 indicates the recess amount of the insulating layer 112 with respect to the insulating layer 111 and the insulating layer 113 in the direction parallel to the main surface 220 of the substrate 200, that corresponds to the groove 150. An inclination θ1 indicates the inclination of a portion of the side wall 161 excluding the groove 150 with respect to the surface 125 of the electrode 120. It can also be said that the inclination θ1 indicates the inclination of the insulating layers 111 and 113 in the side wall 161 with respect to the surface 125 of the electrode 120. Further, the inclination θ1 can be the inclination of a portion of the side wall 161 excluding the groove 150 (or the insulating layers 111 and 113) with respect to the direction parallel to the main surface 220 of the substrate 200.

In this embodiment, the sum of the length H1, the length H2, and the length H3 is smaller than the length T2. It can also be said that the sum of the length H1, the length H2, and the length H3 is the length, in the normal direction of the main surface 220, between the surface 125 of the electrode 120 and a portion of the side wall 161 of the concave portion 160 provided in the insulating layer 110 which is farthest from the main surface 220 of the substrate 200. Each of the length H1, the length H2, the length H3, and the length D1 is larger than the length T1. Furthermore, the inclination θ1 is 50° or more. That is, in this embodiment, following inequalities (1) to (6) hold.

$$H 1 + H 2 + H 3 < T 2 \qquad ( 1 )$$

$$H 1 > T 1 \qquad ( 2 )$$

$$H 2 > T 1 \qquad ( 3 )$$

$$H 3 > T 1 \qquad ( 4 )$$

$$D 1 > T 1 \qquad ( 5 )$$

$$θ1 > 50 ° \qquad ( 6 )$$

By having the relationship expressed by inequalities (1) to (6), the electrode 120 is not covered with the insulating layer 110. In addition, since the groove 150 is arranged, the resistance of the organic functional layer 131 becomes high as described above. Furthermore, the organic functional layer 131 can be thinned or even divided due to the steep angle of the side wall 161 of the concave portion 160 provided in the insulating layer 110 with respect to the surface 125 of the electrode 120. That is, the resistance of the organic functional layer 131 can be made higher. That is, it is possible to suppress a leakage current between the light emitting elements 210 without decreasing the opening ratio of the light emitting element 210.

Next, a manufacturing method of the light emitting device 100 will be described. First, the substrate 200 and the wiring layer 201 are formed. For example, transistors, capacitive elements, wiring patterns, and the like are formed by a known CMOS process. The surface of the uppermost layer of the wiring layer 201 using an insulating material such as silicon oxide, silicon nitride, or silicon oxynitride is planarized by a CMP method or the like after deposition.

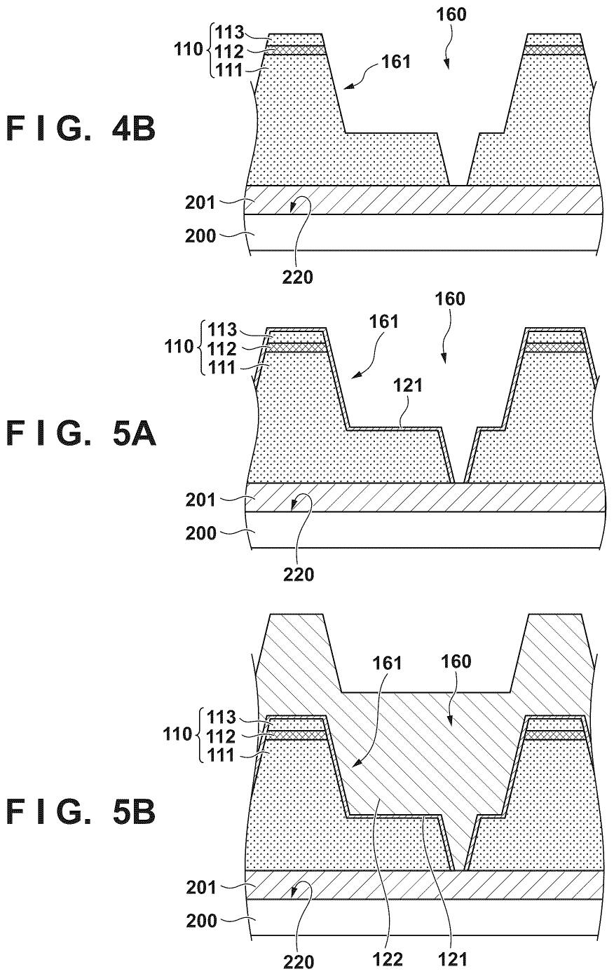

Then, as shown in FIG. 4A, the insulating layers 111, 112, and 113 are deposited as the insulating layer 110 in this order. As described above, a material different from the materials used for the insulating layers 111 and 113 in the selectivity with respect to the etchant used to form the groove 150 is used for the insulating layer 112. For example, silicon oxide may be used as the insulating layers 111 and 113, and silicon nitride may be used as the insulating layer 112. After the insulating layers 111, 112, and 113 are formed as the insulating layer 110, the concave portion 160 is formed as shown in FIG. 4B by using, for example, a photolithography method, an etching method, or the like.

If the insulating layers 111, 112, and 113 are formed of materials different from each other, the etching rate of the insulating layer 113 to form the concave portion 160 may be equal to or higher than the etching rate of the insulating layer 111. The etching rate of the insulating layer 112 to form the concave portion 160 may be higher than the etching rate of the insulating layer 113 and the etching rate of the insulating layer 111. However, the present invention is not limited to this, and the etching rate (selectivity) to form the concave portion 160 may not be significantly different among the insulating layers 111, 112, and 113. It is only required that etching can be performed such that the inclination θ1 of the side wall 161 of the concave portion 160 becomes, for example, 50° or more with respect to the main surface 220 of the substrate 200. The insulating layers 111, 112, and 113 may be formed using a CVD method, a PVD method, an ALD method, or the like as described above. If the insulating layers 111, 112, and 113 are formed of resins using organic materials, they may be formed using a coating method or the like. In addition to formation of the concave portion 160, a contact plug for establishing an electrical connection between the electrode 120 and the wiring pattern in the wiring layer 201 may be formed. Through the steps described above, the insulating layer 110 including the concave portion 160 can be formed on the main surface 220 of the substrate 200.

Although not shown in FIG. 4B, when forming the concave portion 160 or after forming the concave portion 160, by selectively etching the insulating layer 112 with respect to the insulating layers 111 and 113, the groove 150 may be formed before forming the electrode 120. That is, a step of forming the groove 150 may be performed before a step of embedding the electrode 120 in the concave portion 160 provided in the insulating layer 110, which will be described with reference to FIGS. 5A to 8A.

For example, assume a case in which silicon oxide is used as the insulating layers 111 and 113 and silicon nitride is used as the insulating layer 112. In this case, chemical etching (for example, plasma etching) using CF₄ gas is performed. By selecting an appropriate condition, the etching rate of the insulating layer 112 using silicon nitride becomes higher than the etching rate of the insulating layers 111 and 113 using silicon oxide. Thus, the groove 150 depressed, in the direction parallel to the main surface 220 of the substrate 200, from the surface of the side wall 161 of the concave portion 160 formed in the insulating layer 110 is formed. If silicon oxide is used as the insulating layers 111 and 113 and silicon nitride is used as the insulating layer 112, the gas used to form the groove 150 by chemical etching is not limited to CF₄ gas. A CF-based gas such as a perfluorocarbon (PFC) gas represented by CₓF_{y}, such as CF₄ or C₄F₈, or a hydrofluorocarbon (HFC) gas represented by CₓH_{y}F_{z}, such as CHF₃ or C₂H₂F₄, may be used to form the groove 150 by chemical etching.

The formation of the groove 150 is not limited to chemical etching using a CF-based gas. If silicon oxide is used as the insulating layers 111 and 113 and silicon nitride is sued as the insulating layer 112, the groove 150 can be formed by chemical etching (for example, wet etching) using phosphoric acid. For example, if silicon nitride is used as the insulating layers 111 and 113 and silicon oxide is used as the insulating layer 112, the groove 150 can be formed by chemical etching (for example, wet etching) using hydrofluoric acid. The groove 150 may be formed by selecting an appropriate etchant (such as a gas or a solution) and an appropriate etching method (such as plasma (dry) etching or wet etching) in accordance with the materials of the insulating layers 111, 112, and 113 constituting the insulating layer 110.

Then, as shown in FIG. 5A, the conductive layer 121 is deposited using, for example, a sputtering method. To be precise, a conductive material that will become the conductive layer 121 in a subsequent step is formed, but here it is expressed as deposition of “the conductive layer 121”. This applies to other components in a similar manner. The conductive layer 121 can be a barrier metal layer containing titanium and titanium nitride. Then, as shown in FIG. 5B, the conductive layer 122 (conductive material) is deposited using, for example, a sputtering method. The conductive layer 122 can be a reflective metal layer formed of an aluminum alloy.

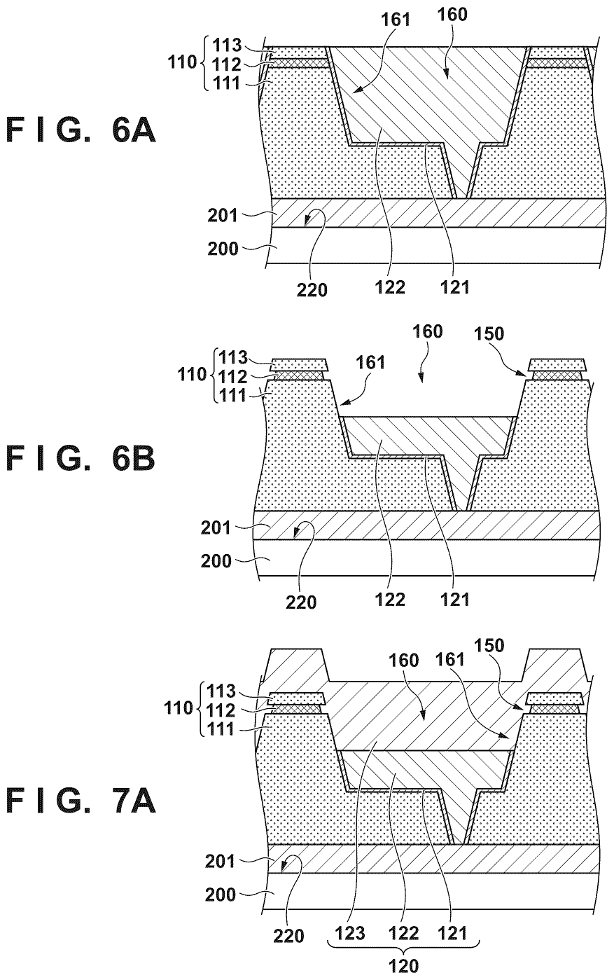

After the conductive layers 121 and 122 (conductive materials) are formed, as shown in FIG. 6A, the surfaces of the conductive layers 121 and 122 (conductive materials) are planarized using, for example, a CMP method. Further, as shown in FIG. 6B, the conductive layers 121 and 122 (conductive materials) are selectively etched with respect to the insulating layer 110. Thus, the conductive layers 121 and 122 are embedded in the concave portion 160 provided in the insulating layer 110, and separated for each light emitting element 210.

The groove 150 may be formed as shown in FIG. 6B by selectively etching the insulating layer 112 with respect to the insulating layer 111 and the insulating layer 113 during or after the step of selectively etching the conductive layers 121 and 122 (conductive materials). In a case of forming the groove 150 after selectively etching the conductive layers 121 and 122 (conductive materials) to separate the conductive layers 121 and 122 for each light emitting element 210, the method as described above can be used. In a case of forming the groove 150 during the step of selectively etching the conductive layers 121 and 122 (conductive materials), the etchant and etching method are selected that allow progress of etching of the insulating layer 112 and the conductive layers 121 and 122 with respect to the insulating layers 111 and 113.

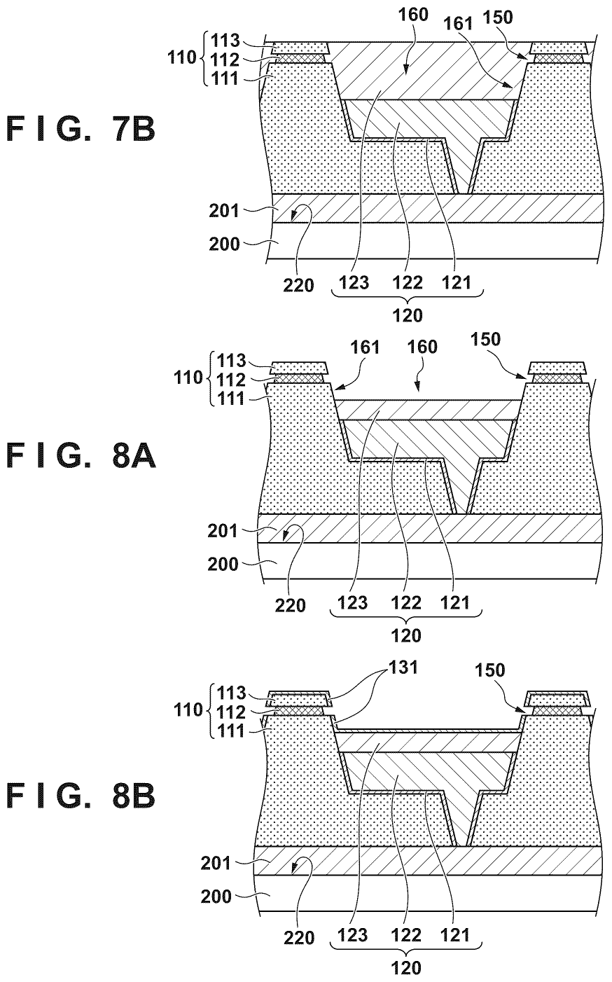

Then, as shown in FIG. 7A, the conductive layer 123 (conductive material) is deposited using, for example, a sputtering method. The conductive layer 123 is a transparent conductive material layer made of indium tin oxide or the like. After the conductive layer 123 (conductive material) is formed, as shown in FIG. 7B, the surface of the conductive layer 123 (conductive material) is planarized using, for example, a CMP method. Further, as shown in FIG. 8A, the conductive layer 123 (conductive material) is selectively etched with respect to the insulating layer 110. Thus, the conductive layer 123 is embedded in the concave portion 160 provided in the insulating layer 110 and separated for each light emitting element 210. Through the steps described above, the electrode 120 including the conductive layers 121, 122, and 123 is arranged in the concave portion 160 provided in the insulating layer 110.

In this embodiment, the groove 150 is formed in the step shown in FIG. 6B, but the groove 150 may be formed not in the step shown in FIG. 6B but in the step shown in FIG. 8A. That is, the groove 150 may be formed by selectively etching the insulating layer 112 with respect to the insulating layer 111 and the insulating layer 113 during or after the step of selectively etching the conductive layer 123 (conductive material). In a case of forming the groove 150 after selectively etching the conductive layer 123 (conductive material) to separate the conductive layer 123 for each light emitting element 210, the method as described above can be used. In a case of forming the groove 150 during the step of selectively etching the conductive layer 123 (conductive material), the etchant and etching method are selected that allow progress of etching of the insulating layer 112 and the conductive layer 123 with respect to the insulating layers 111 and 113. The groove 150 only needs to be formed before the organic functional layer 131 is deposited.

As described above, the manufacturing method according to this embodiment does not need a photolithography technique to form the electrode 120 and the groove 150 after forming the insulating layer 110. Therefore, to form the electrode 120 and the groove 150, it is unnecessary to ensure exposure margins which are required when forming the electrode 120 and the groove 150 using a photolithography method and an etching method. That is, according to the present disclosure, a technique advantageous in miniaturization of the light emitting element 210 is provided.

After the electrode 120 and the groove 150 are formed, as shown in FIG. 8B, the organic functional layer 131 is formed using, for example, a vacuum vapor deposition method. During deposition using the vacuum vapor deposition method, it is possible to selectively deposit a desired layer in a predetermined region (for example, the pixel region where the plurality of light emitting elements 210 are arranged) by using a metal mask. The organic functional layer 131 may be, for example, a hole injection layer, a hole transport layer, or an electron blocking layer as described above, or may have a stacked structure thereof. Since the groove 150 exists in the side wall 161 of the concave portion 160 when forming the organic functional layer 131, for example, the organic functional layer 131 is not formed in the portion of the side wall 161 where the groove 150 is arranged and can be divided at the groove 150. Hence, the resistance of the organic functional layer 131 can become high between the light emitting elements 210 due to the groove 150.

Then, the light emitting layer 132 and the electrode 140 are formed. The light emitting layer 132 and the electrode 140 may be formed using a vacuum vapor deposition method without releasing each component arranged on the substrate 200 from a decompressed atmosphere to the atmosphere following the formation of the organic functional layer 131. Thus, the light emitting element 210 as shown in FIG. 2 is manufactured. An electron transport layer, an electron injection layer, or a hole blocking layer may be formed between the formation of the light emitting layer 132 and the formation of the electrode 140.

As described above, the organic layer 130 including the organic functional layer 131 and the light emitting layer 132 and the electrode 140 may be formed continuously over the whole pixel region where the plurality of light emitting elements 210 are arranged, and may be shared by the plurality of light emitting elements 210. In other words, the organic layer 130 and the electrode 140 may be integrally arranged over the whole pixel region.

Although not shown in FIG. 2, by using, for example, a plasma CVD method, a sputtering method, an ALD method, or the like, a moisture preventing layer may be arranged on the upper surface of the electrode 140 so as to cover the electrode 140. The moisture preventing layer may have a single layer structure of silicon nitride or aluminum oxide or a stacked structure thereof. The moisture preventing layer can be deposited at the deposition temperature equal to or lower than the decomposition temperature of the organic material forming the organic layer 130, for example, at the deposition temperature of 120° C. or less.

Furthermore, a planarizing layer and a color filter may be arranged on the moisture preventing layer. As the planarizing layer, silicon oxide deposited using a CVD method or a sputtering method may be used. Alternatively, for example, a resin of acryl, polyimide, or the like deposited using a coating method may be used as the planarizing layer. As the color filter, for example, a color filter that transmits red light may be formed by coating a material for a red filter and patterning it using a photolithography method. Similarly, color filters that transmit green light and blue light, respectively, may be formed. The planarizing layer and color filter can be formed at a temperature equal to or lower than the decomposition temperature of the organic material forming the organic layer 130, for example, at a temperature of 120° C. or less. Furthermore, a planarizing layer and a microlens may be arranged on the color filter. The microlens can be formed by coating a resin material and patterning it using a photolithography method. Similar to the planarizing layer and the color filter, the microlens can be formed at a temperature equal to or lower than the decomposition temperature of the organic material forming the organic layer 130, for example, at a temperature of 120° C. or less.

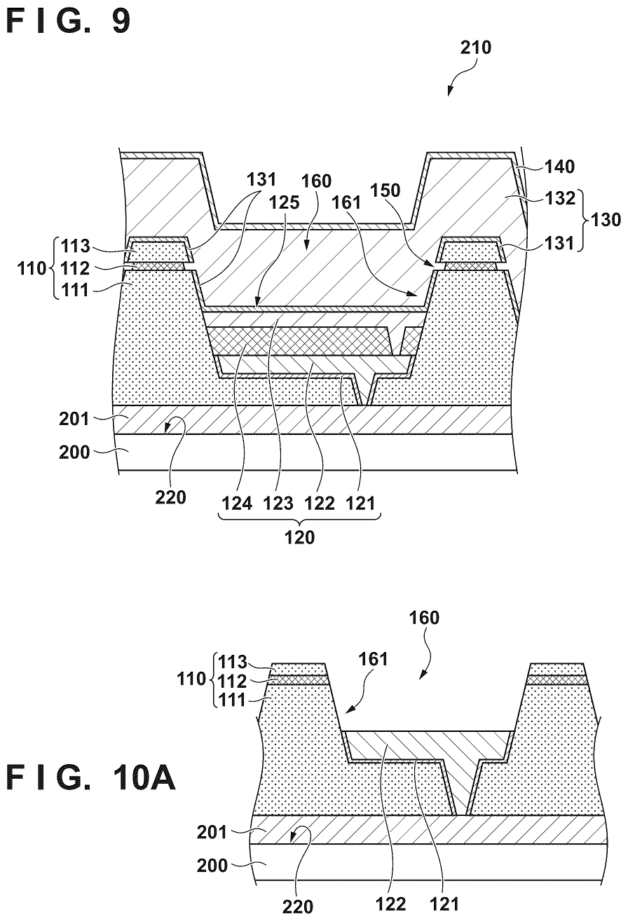

FIG. 9 is a sectional view taken along the line A-A′ in FIG. 1, and showing a modification of the light emitting element 210 shown in FIG. 2. Compared to the light emitting element 210 shown in FIG. 2, in the light emitting element 210 shown in FIG. 9, the electrode 120 further includes an insulating layer 124 arranged between the conductive layer 122 and the conductive layer 123. The remaining arrangement may be similar to that of the light emitting element 210 described above, so that the different arrangement will be mainly described here and a description of the arrangement that may be similar to the above-described arrangement will be omitted, as appropriate.

The insulating layer 124 may be formed using, for example, a CVD method, a PVD method, an ALD method, a coating method, or the like. For the insulating layer 110, an inorganic material such as silicon oxide, silicon nitride, silicon oxynitride, silicon carbide, carbon-containing silicon oxide, or aluminum oxide, or an organic material such as acryl or polyimide may be used. By setting the film thickens of the insulating layer 124 to an appropriate value, the light emission efficiency of the light emitting element 210 can be increased. The conductive layer 122 and the conductive layer 123 are electrically connected by a conductor arranged in a through hole provided in the insulating layer 124. For example, as shown in FIG. 9, the conductive layer 122 and the conductive layer 123 are electrically connected by embedding a conductive material for the conductive layer 123 in the through hole provided in the insulating layer 124 during formation of the conductive layer 123.

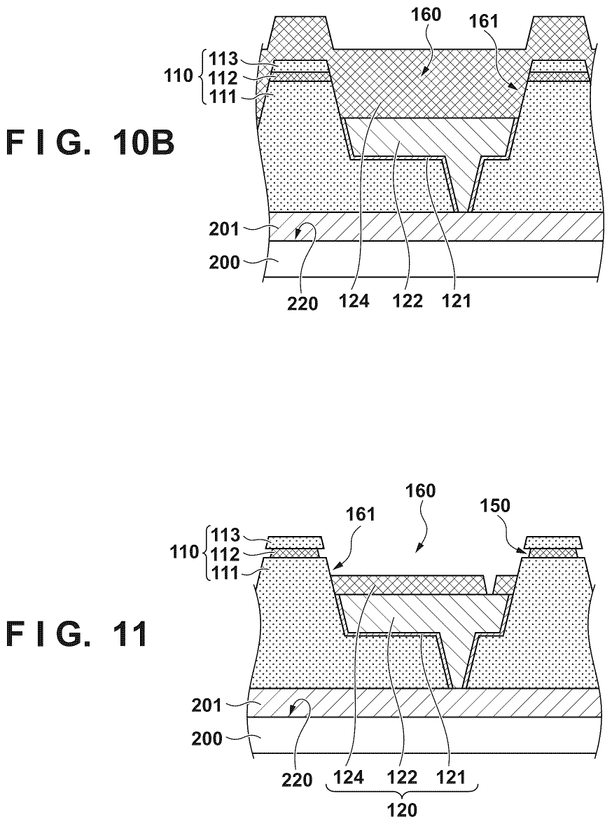

Next, a manufacturing method of the light emitting element 210 shown in FIG. 9 will be described. After the steps described using FIGS. 4A to 6A, the conductive layers 121 and 122 (conductive materials) are selectively etched with respect to the insulating layer 110 as shown in FIG. 10A. Thus, the conductive layers 121 and 122 are embedded in the concave portion 160 provided in the insulating layer 110, and separated for each light emitting element 210. At this time, in this embodiment, the groove 150 is not formed unlike the step shown in FIG. 6B.

After the conductive layers 121 and 122 are separated for each pixel, the insulating layer 124 (insulating material) is deposited as shown in FIG. 10B. The insulating layer 124 may be a layer containing a material different from the materials for the insulating layers 111, 112, and 113. The insulating layer 124 may contain a material different from the materials for the insulating layers 111, 112, and 113 in the etching rate with respect to a predetermined etchant.

After the insulating layer 124 (insulating material) is formed, the surface of the insulating layer 124 (insulating material) is planarized using, for example, a CMP method. Further, as shown in FIG. 11, the insulating layer 124 (insulating material) is selectively etched with respect to the insulating layer 110. Thus, the insulating layer 124 is embedded in the concave portion 160 provided in the insulating layer 110, and separated for each light emitting element 210. At this time, a through hole extending through the insulating layer 124 and exposing the conductive layer 121 may be formed.

In this embodiment, the groove 150 is formed in a step shown in FIG. 11. That is, the groove 150 may be formed by selectively etching the insulating layer 112 with respect to the insulating layer 111 and the insulating layer 113 during or after the step of selectively etching the insulating layer 124 (insulating material). In a case of forming the groove 150 after selectively etching the insulating layer 124 (insulating material) to separate the insulating layer 124 for each light emitting element 210, the method as described above can be used.

In a case of forming the groove 150 during the step of selectively etching the insulating layer 124 (insulating material), the etchant and etching method are selected that allow progress of etching of the insulating layers 112 and 124 with respect to the insulating layers 111 and 113. For example, the insulating layers 111 and 113 may be formed of the same material, and the insulating layers 112 and 124 may be formed of the same material which is different from the material for the insulating layers 111 and 113. For example, if silicon oxide is used for the insulating layers 111 and 113 and silicon nitride is used for the insulating layers 112 and 124, the groove 150 can be formed while selectively etching the insulating layer 124 (insulating material) by chemical etching using a CF-based gas or phosphoric acid. For example, if silicon nitride is used for the insulating layers 111 and 113 and silicon oxide is used for the insulating layers 112 and 124, the groove 150 can be formed while selectively etching the insulating layer 124 (insulating material) by chemical etching using hydrofluoric acid. The above-described length D1 can be controlled by controlling the etchant and etching method, and the film thickness upon depositing the insulating layer 112.

Steps after the step shown in FIG. 11 may be similar to the steps from the step shown in FIG. 7A described above, so that a description will be omitted here. The groove 150 may be formed in the step shown in FIG. 11, but the present invention is not limited thereto. The groove 150 may be formed in the step shown in FIG. 10A (FIG. 6A) as in the above description, may be formed before depositing the conductive layer 121, or may be formed in the step of selectively etching the conductive layer 123 with respect to the insulating layer 110 shown in FIG. 8A.

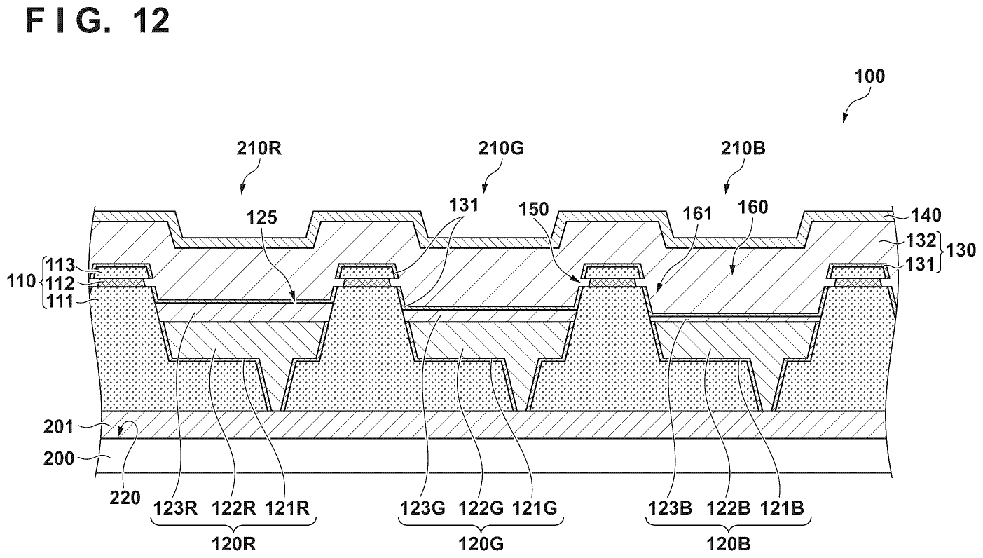

FIG. 12 is a sectional view taken along a line C-C′ in FIG. 1, and showing the light emitting device 100 including the light emitting element 210 which is a modification of the light emitting element 210 shown in FIG. 2. As shown in FIG. 12, the light emitting device 100 may include the light emitting element 210 including the conductive layer 123 whose film thickness changes in accordance with the light emission wavelength. The remaining arrangement may be similar to that of the light emitting device 100 and light emitting element 210 described above, so that the different arrangement will be mainly described here and a description of the arrangement that may be similar to the above-described arrangement will be omitted, as appropriate.

As shown in FIG. 12, the electrode 120 of a light emitting element 210R that emits red light includes a conductive layer 123R, the electrode 120 of a light emitting element 210B that emits blue light includes a conductive layer 123B, and the electrode 120 of a light emitting element 210G that emits green light includes a conductive layer 123G. In this case, the length of the conductive layer 123R arranged in the light emitting element 210R in the normal direction of the main surface 220 of the substrate 200 is different from the length of the conductive layer 123B arranged in the light emitting element 210B in the normal direction of the main surface 220 of the substrate 200. In addition, the length of the conductive layer 123R arranged in the light emitting element 210R in the normal direction of the main surface 220 of the substrate 200 is different from the length of the conductive layer 123G arranged in the light emitting element 210G in the normal direction of the main surface 220 of the substrate 200. Similarly, the length of the conductive layer 123B arranged in the light emitting element 210B in the normal direction of the main surface 220 of the substrate 200 is different from the length of the conductive layer 123G arranged in the light emitting element 210G in the normal direction of the main surface 220 of the substrate 200. The lengths of the conductive layers 123R, 123B, and 123G in the normal direction of the main surface 220 of the substrate 200 can also be referred to as the film thicknesses of the conductive layers 123R, 123B, and 123G, respectively. As shown in FIG. 12, the film thickness of the conductive layer 123R may be the largest, the film thickness of the conductive layer 123G may be the second largest, and the film thickness of the conductive layer 123B may be the smallest.

As described above, by setting the film thickness of the conductive layer 123 as a transparent electrode layer to an appropriate value, the light emission efficiency of the light emitting element 210 can be increased. That is, the film thicknesses of the conductive layers 123R, 123B, and 123G can be selected from the film thicknesses that can enhance the light emission wavelengths of the light emitting elements 210R, 210B, and 210G with each other.

The light emitting device 100 shown in FIG. 12 can be implemented by, for example, forming the conductive layers 123R, 123B, and 123G for the light emitting elements 210R, 210B, and 210G, respectively, in a step after the step of depositing the conductive material for the conductive layer 123 shown in FIG. 7A. For example, in the planarizing step shown in FIG. 7B or the step of selectively etching the conductive layer 123 with respect to the insulating layer 110 shown in FIG. 8A, the etching amount is changed for each of the conductive layers 123R, 123B, and 123G. With this, the light emitting device 100 and light emitting element 210 shown in FIG. 12 can be manufactured.

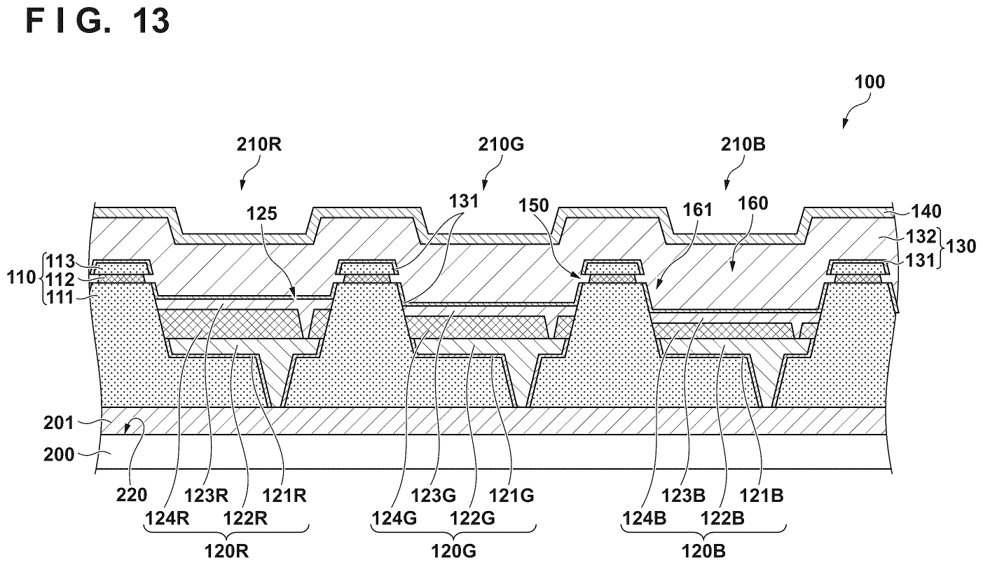

FIG. 13 is a sectional view taken along the line C-C′ in FIG. 1, and showing the light emitting device 100 including the light emitting element 210 which is a modification of the light emitting element 210 shown in FIG. 9. As shown in FIG. 13, the light emitting device 100 may include the light emitting element 210 including the insulating layer 124 whose film thickness changes in accordance with the light emission wavelength. The remaining arrangement may be similar to that of the light emitting device 100 and light emitting element 210 described above, so that the different arrangement will be mainly described here and a description of the arrangement that may be similar to the above-described arrangement will be omitted, as appropriate.

As shown in FIG. 13, the electrode 120 of the light emitting element 210R that emits red light includes an insulating layer 124R, the electrode 120 of the light emitting element 210B that emits blue light includes an insulating layer 124B, and the electrode 120 of the light emitting element 210G that emits green light includes an insulating layer 124G. In this case, the length of the insulating layer 124R arranged in the light emitting element 210R in the normal direction of the main surface 220 of the substrate 200 is different from the length of the insulating layer 124B arranged in the light emitting element 210B in the normal direction of the main surface 220 of the substrate 200. In addition, the length of the insulating layer 124R arranged in the light emitting element 210R in the normal direction of the main surface 220 of the substrate 200 is different from the length of the insulating layer 124G arranged in the light emitting element 210G in the normal direction of the main surface 220 of the substrate 200. Similarly, the length of the insulating layer 124B arranged in the light emitting element 210B in the normal direction of the main surface 220 of the substrate 200 is different from the length of the insulating layer 124G arranged in the light emitting element 210G in the normal direction of the main surface 220 of the substrate 200. The lengths of the insulating layers 124R, 124B, and 124G in the normal direction of the main surface 220 of the substrate 200 can also be referred to as the film thicknesses of the insulating layers 124R, 124B, and 124G. As shown in FIG. 13, the film thickness of the insulating layer 124R may be the largest, the film thickness of the insulating layer 124G may be the second largest, and the film thickness of the insulating layer 124B may be the smallest.

As described above, by setting the film thickness of the insulating layer 124 to an appropriate value, the light emission efficiency of the light emitting element 210 can be increased. That is, the film thicknesses of the insulating layers 124R, 124B, and 124G can be selected from the film thicknesses that can enhance the light emission wavelengths of the light emitting elements 210R, 210B, and 210G with each other.

The light emitting device 100 shown in FIG. 13 can be implemented by, for example, forming the insulating layers 124R, 124B, and 124G for the light emitting elements 210R, 210B, and 210G, respectively, in a step after the step of depositing the insulating material for the insulating layer 124 shown in FIG. 9A. For example, in the planarizing step or the step of selectively etching the insulating layer 124 with respect to the insulating layer 110 shown in FIG. 11, the etching amount is changed for each of the insulating layers 124R, 124B, and 124G. With this, the light emitting device 100 and light emitting element 210 shown in FIG. 13 can be manufactured.

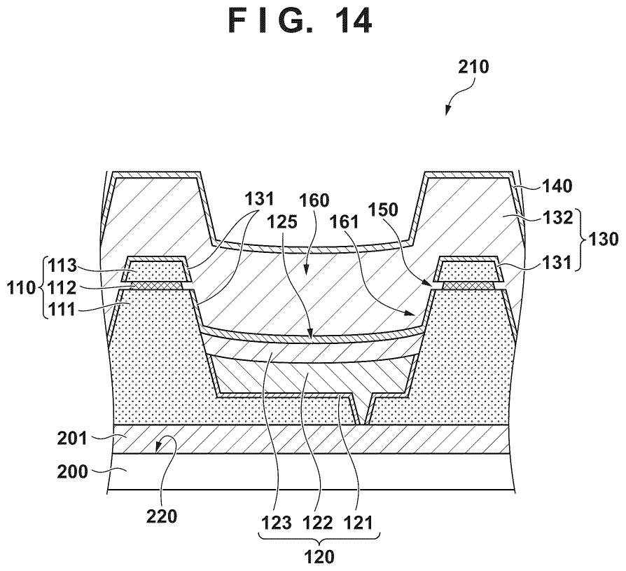

FIG. 14 is a sectional view taken along the line A-A′ in FIG. 1, and showing a modification of the light emitting element 210 shown in FIG. 2. Compared to the light emitting element 210 shown in FIG. 2, in the light emitting element 210 shown in FIG. 14, the surface 125 of the electrode 120 has a concave shape with the central portion recessed more than the other portion in the direction of the main surface 220 of the substrate 200. For example, as shown in FIG. 14, the conductive layer 122 of the electrode 120 is formed to have a concave shape with the central portion recessed more than the other portion in the direction of the main surface 220 of the substrate 200. Along with this, the surface 125 of the electrode 120 as the upper surface of the conductive layer 123 has a concave shape. Similarly, a portion, arranged on the electrode 120, of each of the upper surface of the organic layer 130 including the organic functional layer 131 and the light emitting layer 132 and the upper surface of the electrode 140 may have a concave shape as shown in FIG. 14. The remaining arrangement may be similar to that of the light emitting element 210 described above, so that the different arrangement will be mainly described here and a description of the arrangement that may be similar to the above-described arrangement will be omitted, as appropriate.

As described above, the conductive layer 122 functions as a reflective metal layer. Of light emitted from the light emitting layer 132, the light traveling in the direction of the electrode 120 is reflected at the conductive layer 122 functioning as the reflective metal layer and extracted from the light emitting element 210. When the upper surface of the conductive layer 122 functioning as the reflective metal layer has a concave shape recessed in the direction of the main surface 220 of the substrate 200, it is suppressed that the light reflected at the conductive layer 122 travels outward from the light emitting element 210. As a result, the light emission efficiency of the light emitting device 100 can be improved.

For the light emitting element 210 shown in FIG. 14, in a step after the step of depositing the conductive material for the conductive layer 122 shown in FIG. 5B, the condition for the planarization step shown in FIG. 6A or the step of etching the conductive layer 122 shown in FIG. 6B is adjusted to an appropriate condition. With this, it is possible to form the upper surface of the conductive layer 122 into a concave shape recessed in the direction of the main surface 220 of the substrate 200.

When the shape shown in FIG. 14 is provided, the length T1 described above may indicate the film thickness, in the normal direction of the main surface 220, of the organic functional layer 131 arranged at the geometric centroid position of the electrode 120 in the orthogonal projection to the main surface 220 of the substrate 200. Similarly, the length T2 may indicate the film thickness, in the normal direction of the main surface 220, of the organic layer 130 excluding the organic functional layer 131 arranged at the geometric centroid position of the electrode 120 in the orthogonal projection to the main surface 220 of the substrate 200.

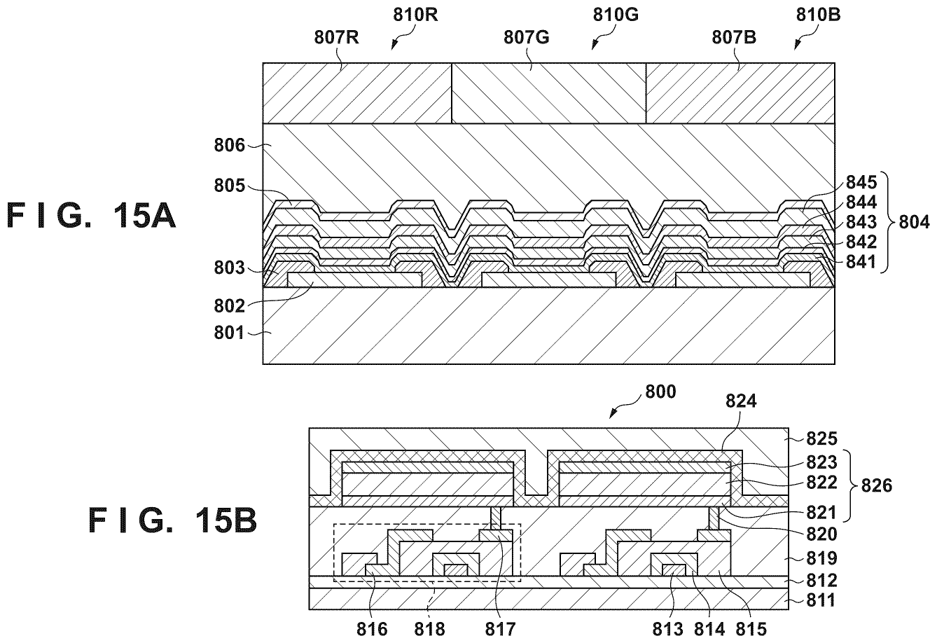

Here, application examples in which the light emitting device 100 according to this embodiment is applied to an image forming device, a display device, a photoelectric conversion device, an electronic apparatus, an illumination device, a moving body, and a wearable device will be described with reference to FIGS. 15A to 23B. The description will be given assuming that, for example, an organic light emitting element (OLED) such as an organic EL element using an organic light emitting material is arranged in the light emitting element 210 (to be sometimes referred to as the pixel or sub-pixel) arranged in the light emitting device 100. Details of each component arranged in the light emitting element 210 of the light emitting device 100 described above will be described first, and the application examples will be described after that.

The organic light emitting element according to an embodiment of the present disclosure includes a first electrode, a second electrode, and an organic compound layer arranged between these electrodes. One of the first electrode and the second electrode is an anode, and the other is a cathode. In the organic light emitting element according to this embodiment, the organic compound layer may be either a single layer or a stacked body formed by a plurality of layers as long as it includes a light emitting layer. Here, if the organic compound layer is a stacked body formed from a plurality of layers, the organic compound layer may include a hole injection layer, a hole transport layer, an electron blocking layer, a hole/exciton blocking layer, an electron transport layer, an electron injection layer, and the like in addition to the light emitting layer. The light emitting layer may be a single layer or a stacked body formed from a plurality of layers. If the light emitting layer includes a plurality of layers, a charge generation layer may be arranged between the light emitting layers. The charge generation layer may be made of a compound having the LUMO lower than that of the hole transport layer, and the LUMO of the charge generation layer may be lower than the HOMO of the hole transport layer. Here, the molecular orbital energy of the organic compound layer may be the molecular orbital energy of the organic compound with the largest weight ratio in the organic compound layer.

The description is given here assuming that the closer the HOMO and LUMO are to the vacuum level, the “higher” they are. When the LUMO of the charge generation layer is lower than the HOMO of the hole transport layer, the LUMO of the charge generation layer is closer to the vacuum level than the HOMO of the hole transport layer.

The HOMO and LUMO in this specification can be calculated using molecular orbital calculation. The molecular orbital calculation is executed by a Density Functional Theory (DFT) or the like. A functional may be calculated using B3LYP, and a basic function may be calculated using 6-31G*. Note that molecular orbital calculation can be executed using, for example, Gaussian 09 (Gaussian 09, Revision C.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y Honda, O. Kitao, H. Nakai, T. Vreven, J. A. Montgomery Jr., J. E. Peralta, F. Ogliaro, M. Bearpark, J. J. Heyd, E. Brothers, K. N. Kudin, VN. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2010.)

The HOMO and LUMO in this specification can be calculated using the ionization potential and band gap. The HOMO can be estimated by measuring the ionization potential. The ionization potential can be measured by dissolving the compound to be measured in a solvent such as toluene and using a measuring device such as AC-3. The band gap can be measured by dissolving the compound to be measured in a solvent such as toluene and irradiating it with excitation light. The band gap can be measured by measuring the absorption edge of the excitation light. Alternatively, the band gap can be measured by depositing the compound to be measured on a substrate such as glass, and exposing the deposited film to excitation light. The band gap can be measured by measuring the absorption edge of the absorption spectrum at which the deposited film absorbs excitation light.

The LUMO can be calculated using the band gap and ionization potential value. The LUMO can be estimated by subtracting the ionization potential value from the band gap.

The LUMO can also be estimated from the reduction potential. For example, the one-electron reduction potential is estimated using cyclic voltammetry (CV) measurement. The CV measurement can be performed, for example, in a DMF solution of 0.1 M tetrabutylammonium perchlorate using a reference electrode of Ag/Ag⁺, a counter electrode of Pt, and a working electrode of glassy carbon. The LUMO can be estimated by adding −4.8 eV to the difference between the reduction potential of the obtained compound and that of ferrocene.

If the organic compound according to this embodiment is contained in the light emitting layer, the light emitting layer may be a layer made of only the organic compound according to this embodiment or a layer made of the organic metal complex according to this embodiment and another compound. Here, if the light emitting layer is a layer made of the organic metal complex according to this embodiment and another compound, the organic compound according to this embodiment may be used as a host or a guest of the light emitting layer. Alternatively, the organic compound may be used as an assist material that can be contained in the light emitting layer. Here, the host is a compound whose mass ratio is largest in the compounds forming the light emitting layer. The guest is a compound whose mass ratio is smaller than that of the host in the compounds forming the light emitting layer, and is a compound responsible for main light emission. The assist material is a compound whose mass ratio is smaller than that of the host in the compounds forming the light emitting layer, and which assists light emission of the guest. Note that the assist material is also called a second host. The host material can be called a first compound, and the assist material as a second compound.

If the organic compound according to an embodiment of the present disclosure is used as the guest of the light emitting layer, the concentration of the guest may be 0.01 mass % (inclusive) to 20 mass % (inclusive) relative to the entire light emitting layer, or may be 0.1 mass % (inclusive) to 10 mass % (inclusive). The guest is also called a dopant.

The organic metal complex according to this embodiment can be used as the constituent material of the organic compound layer other than the light emitting layer forming the organic light emitting element according to this embodiment. More specifically, the organic metal complex may be used as the constituent material of an electron transport layer, an electron injection layer, a hole transport layer, a hole injection layer, a hole blocking layer, or the like. In this case, the light emission color of the organic light emitting element is not limited to red. More specifically, it may be white or an intermediate color.

A conventionally known low molecular and high molecular hole injection compound or hole transport compound, a compound serving as a host, a light emitting compound, an electron injection compound or electron transport compound, or the like can be used together as needed. Examples of these compounds will be described below.

As a hole injection/transport material, a material that has a high hole mobility such that hole injection from the anode is facilitated, and injected holes can be transported to the light emitting layer can suitably be used. Also, a material having a high glass transition point temperature can suitably be used to reduce degradation of film quality such as crystallization in the organic light emitting element. Examples of low molecular and high molecular materials having hole injection/transport performance are a triarylamine derivative, an arylcarbazole derivative, a phenylenediamine derivative, a stilbene derivative, a phthalocyanine derivative, a porphyrin derivative, a poly(vinyl carbazole), a poly(thiophene), and other conductive polymers. The above-described hole injection/transport material can suitably be used for the electron blocking layer as well. Detailed examples of compounds used as the hole injection/transport material will be shown below. The material is not limited to these.

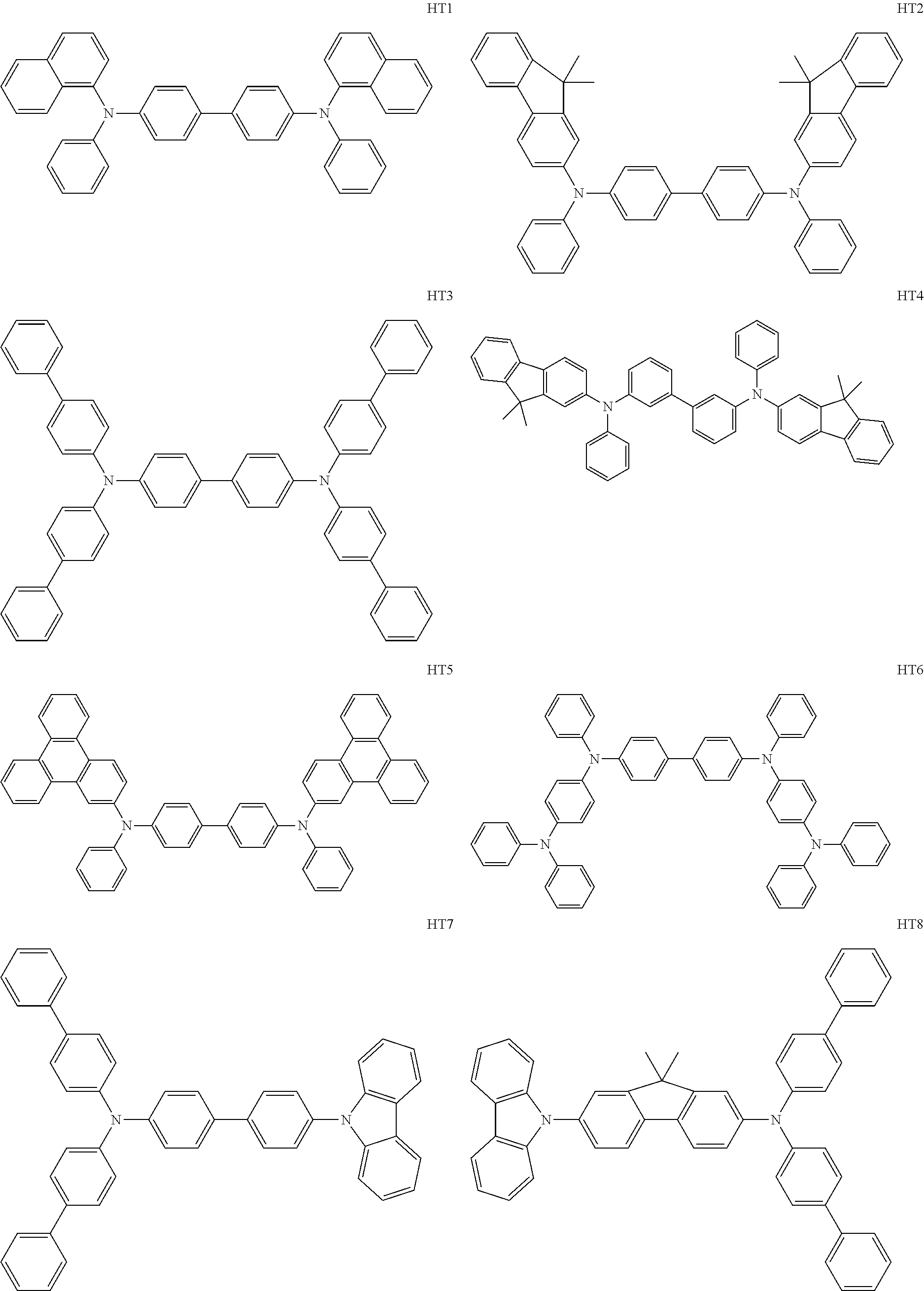

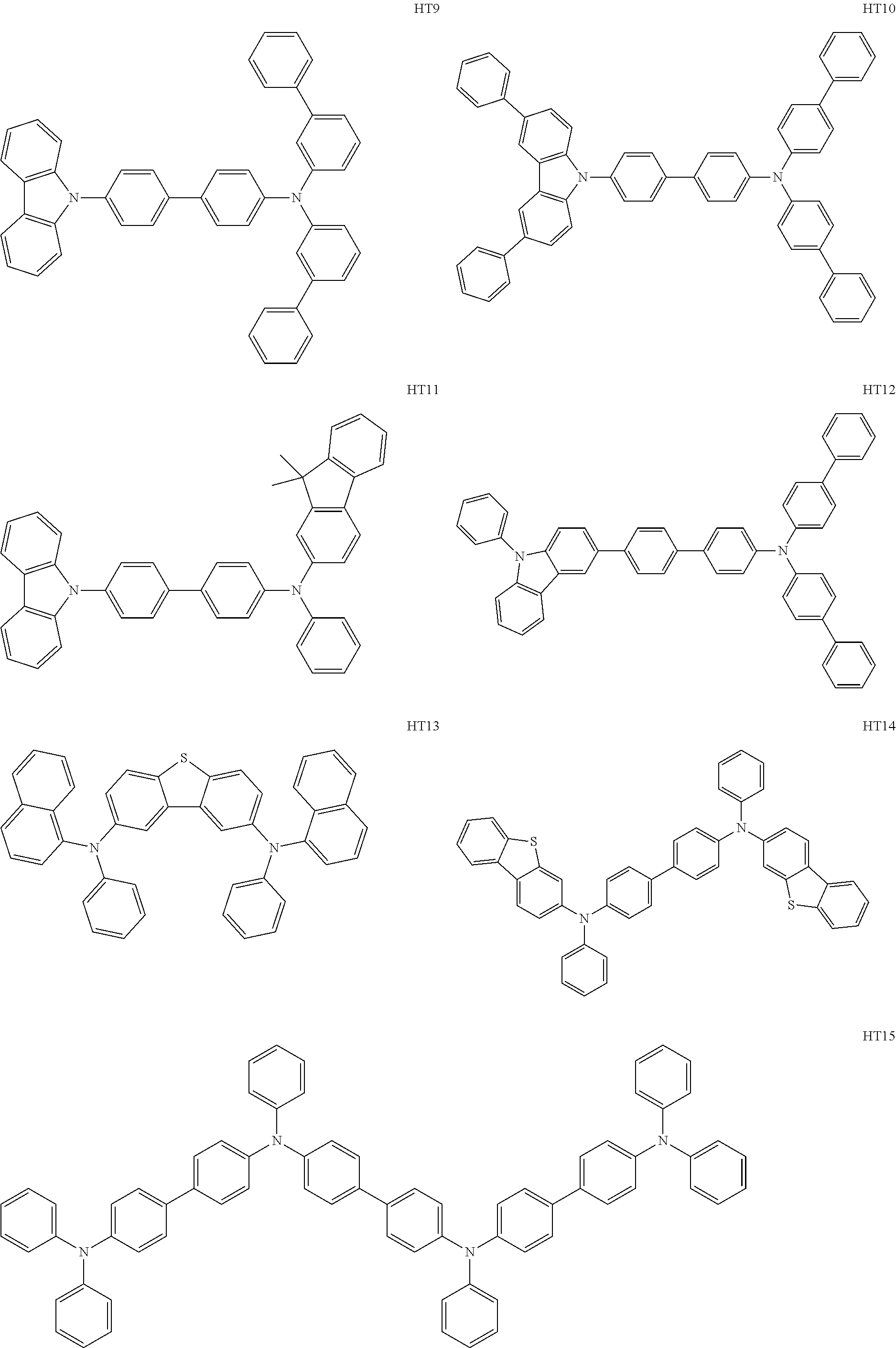

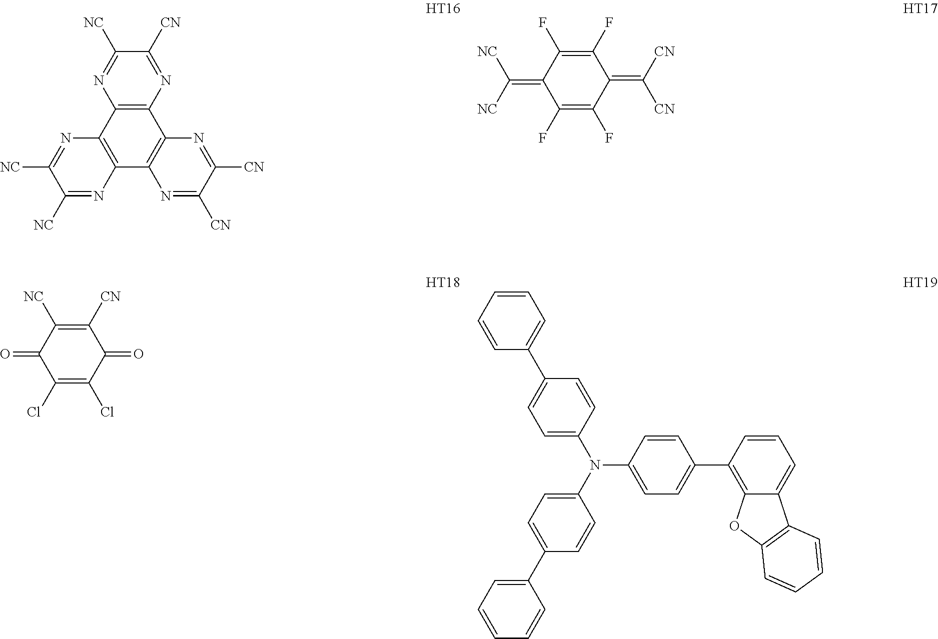 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F ; N#CC1=C(C#N)C(=O)C(Cl)=C(Cl)C1=O ; c1ccc(-c2ccc(N(c3ccc(-c4ccccc4)cc3)c3ccc(-c4cccc5c4oc4ccccc45)cc3)cc2)cc1]

In the hole transport materials, HT16 to HT18 can decrease the driving voltage when used in a layer in contact with the anode. HT16 is widely used in an organic light emitting element. HT2, HT3, HT4, HT5, HT6, HT10, and HT12 can be used in an organic compound layer adjacent to HT16. A plurality of materials may be used in one organic compound layer.

Examples of the light emitting material mainly concerning the light emitting function are condensed-ring compounds (for example, a fluorene derivative, a naphthalene derivative, a pyrene derivative, a perylene derivative, a tetracene derivative, an anthracene derivative, and rubrene), a quinacridone derivative, a coumarin derivative, a stilbene derivative, an organic aluminum complex such as tris(8-quinolinolato)aluminum, an iridium complex, a platinum complex, a rhenium complex, a copper complex, a europium complex, a ruthenium complex, and polymer derivatives such as a poly(phenylenevinylene) derivative, a poly(fluorene) derivative, and a poly(phenylene) derivative.

Detailed examples of compounds used as the light emitting material will be shown below. The material is not limited to these.

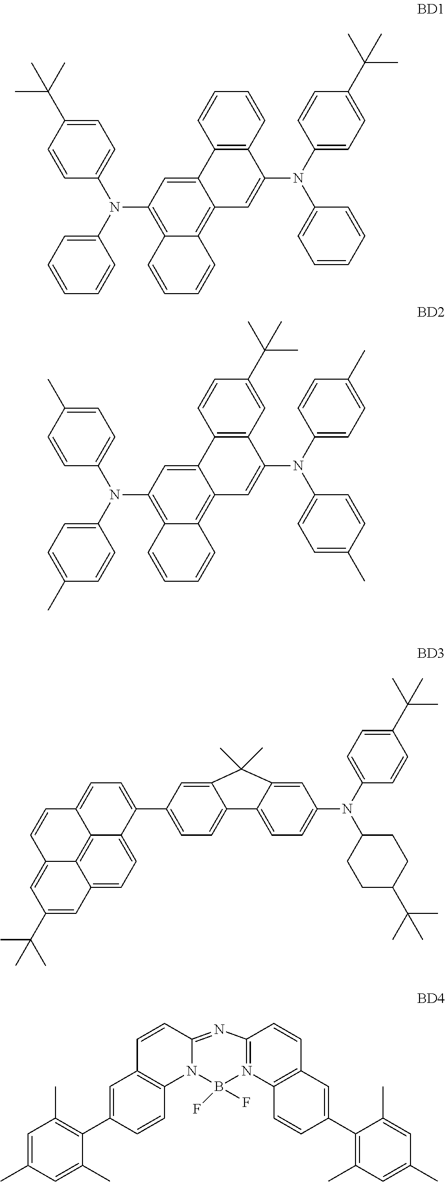

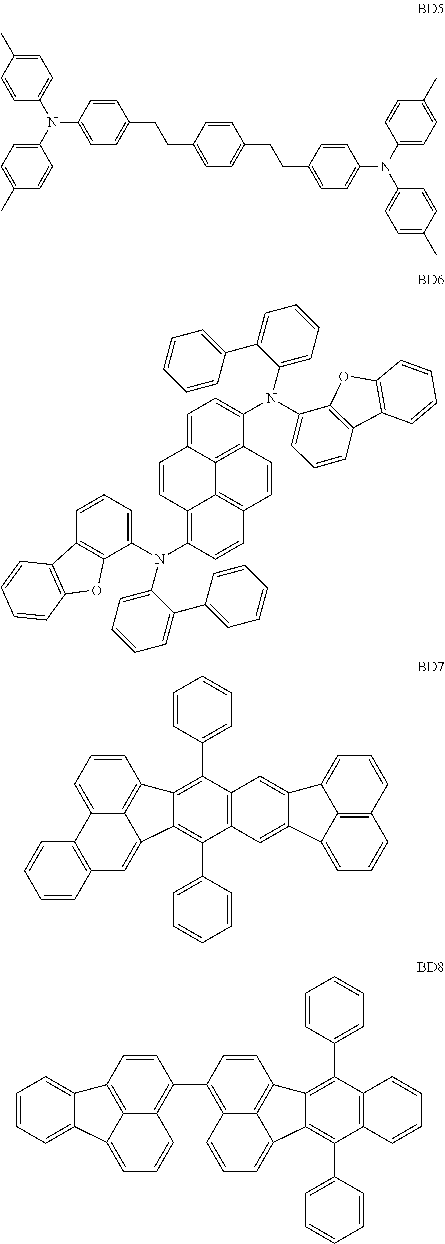

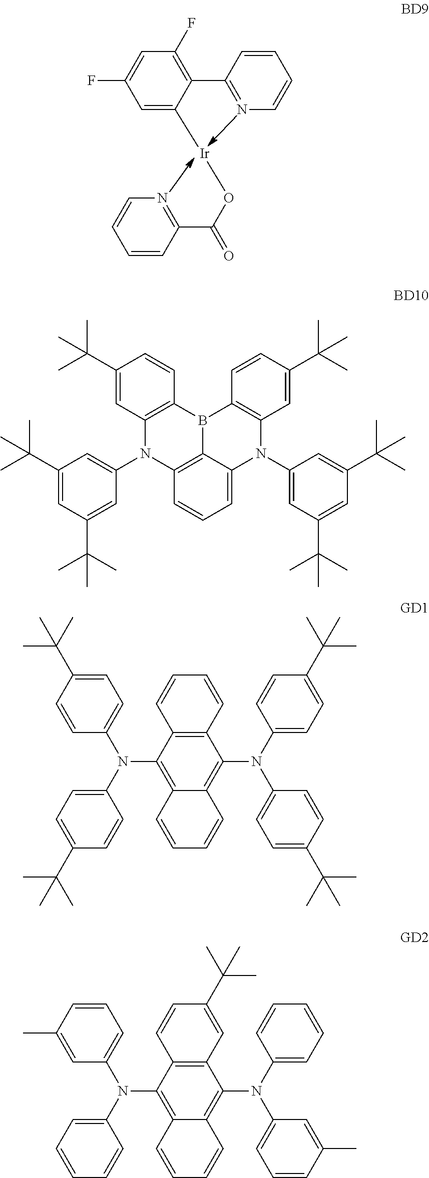

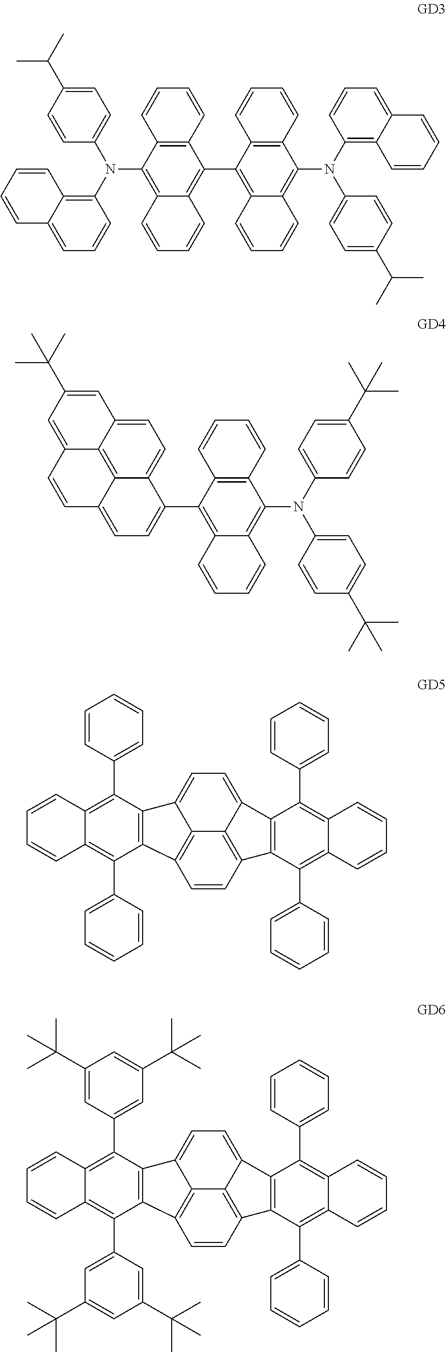

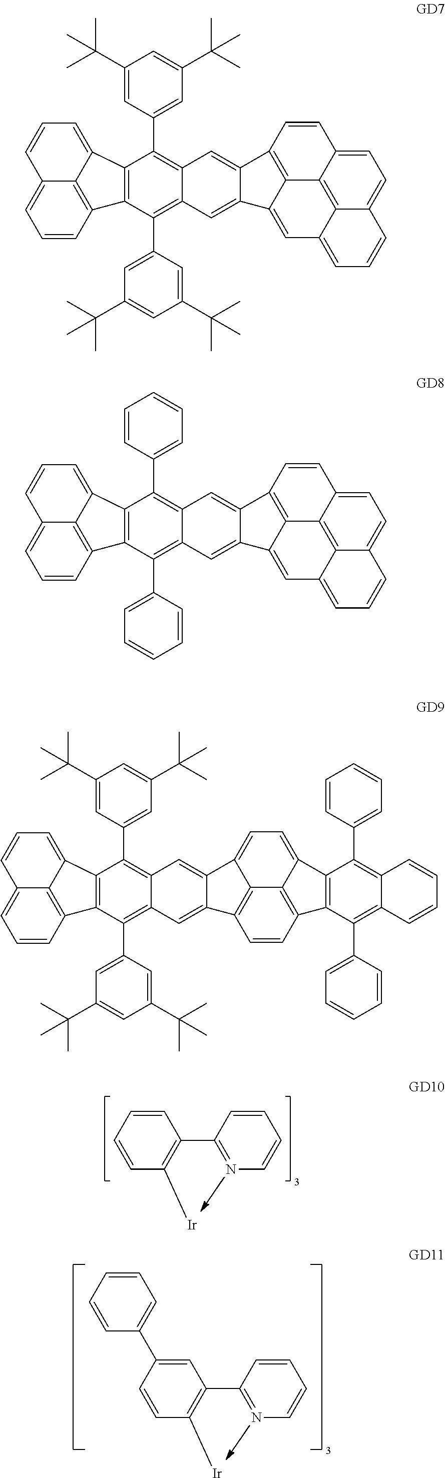

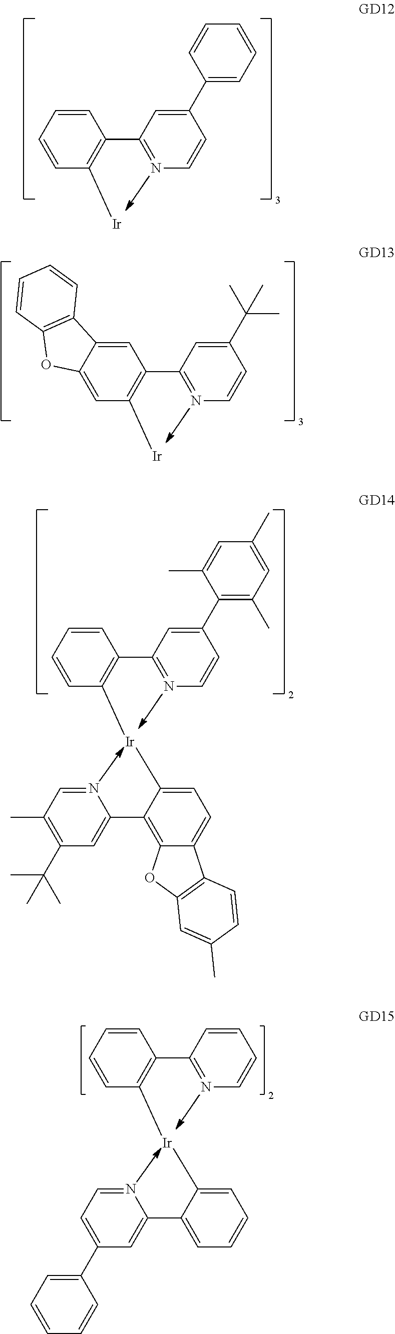

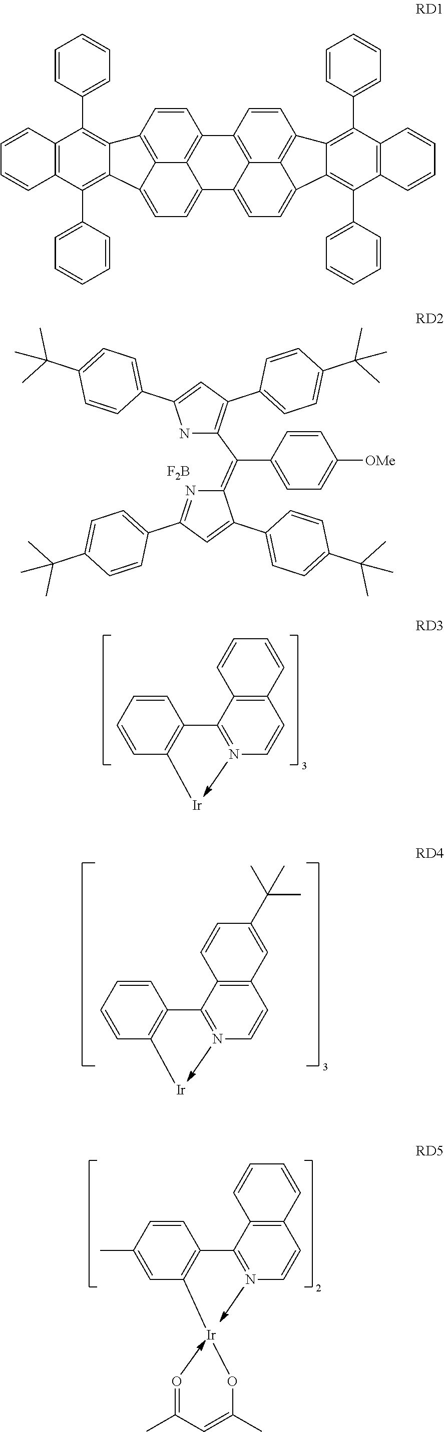

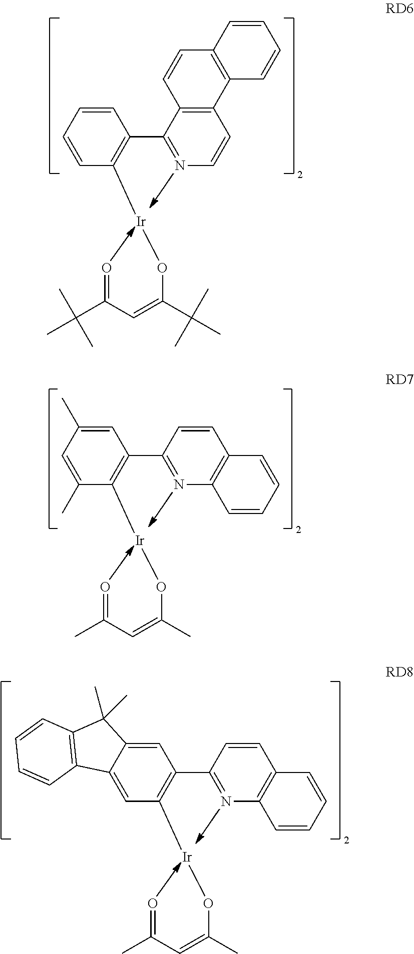

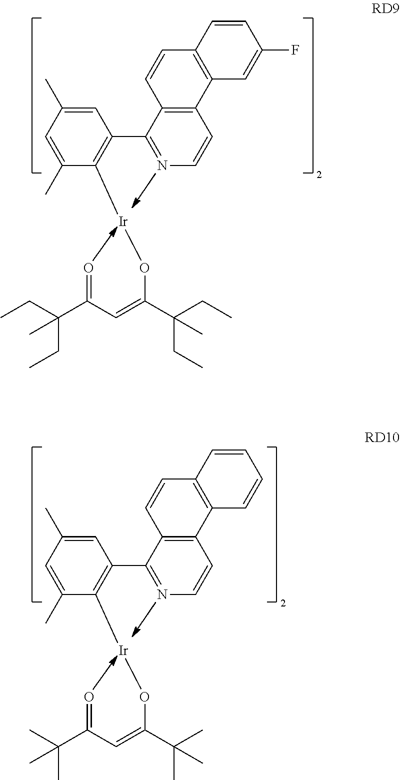

If the light emitting material is a hydrocarbon compound, this is suitable because it is possible to reduce lowering of light emission efficiency caused by exciplex formation or lowering of color purity due to a change of the light emission spectrum of the light emitting material caused by exciplex formation.

The hydrocarbon compound is a compound made of only carbon and hydrogen, and includes BD7, BD8, GD5 to GD9, and RD1 in the compounds exemplified above.

If the light emitting material is a condensed polycyclic compound including a 5-membered ring, this is suitable because oxidation hardly occurs because of a high ionization potential, and a long-life element with high durability can be obtained. This includes BD7, BD8, GD5 to GD9, and RD1 in the compounds exemplified above.

Examples of the light emitting layer host or the light emission assist material contained in the light emitting layer are an aromatic hydrocarbon compound or its derivative, a carbazole derivative, a dibenzofuran derivative, a dibenzothiophene derivative, an organic aluminum complex such as tris(8-quinolinolato)aluminum, and an organic beryllium complex.

Detailed examples of compounds used as the light emitting layer host or the light emission assist material contained in the light emitting layer will be shown below. The material is not limited to these.

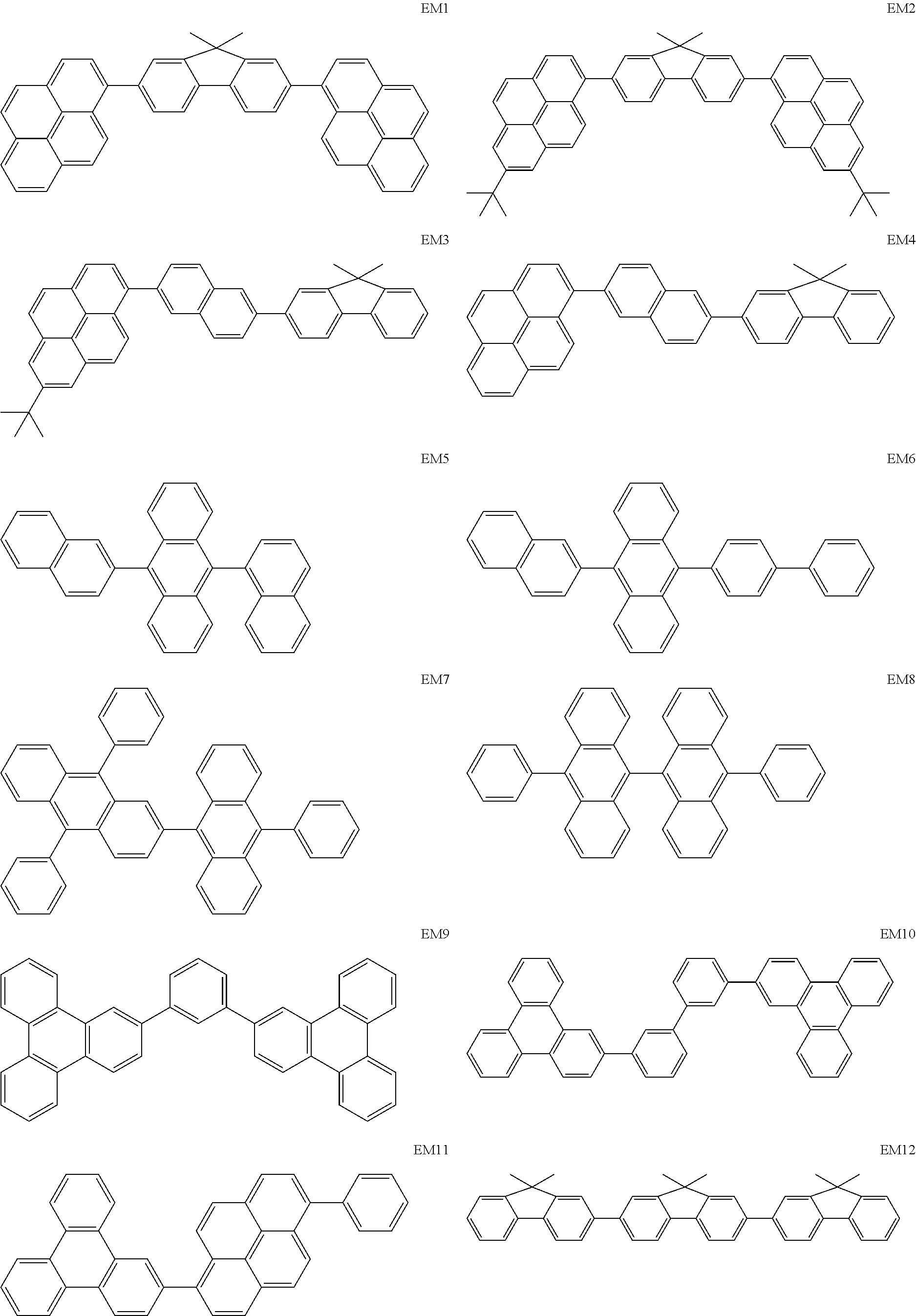

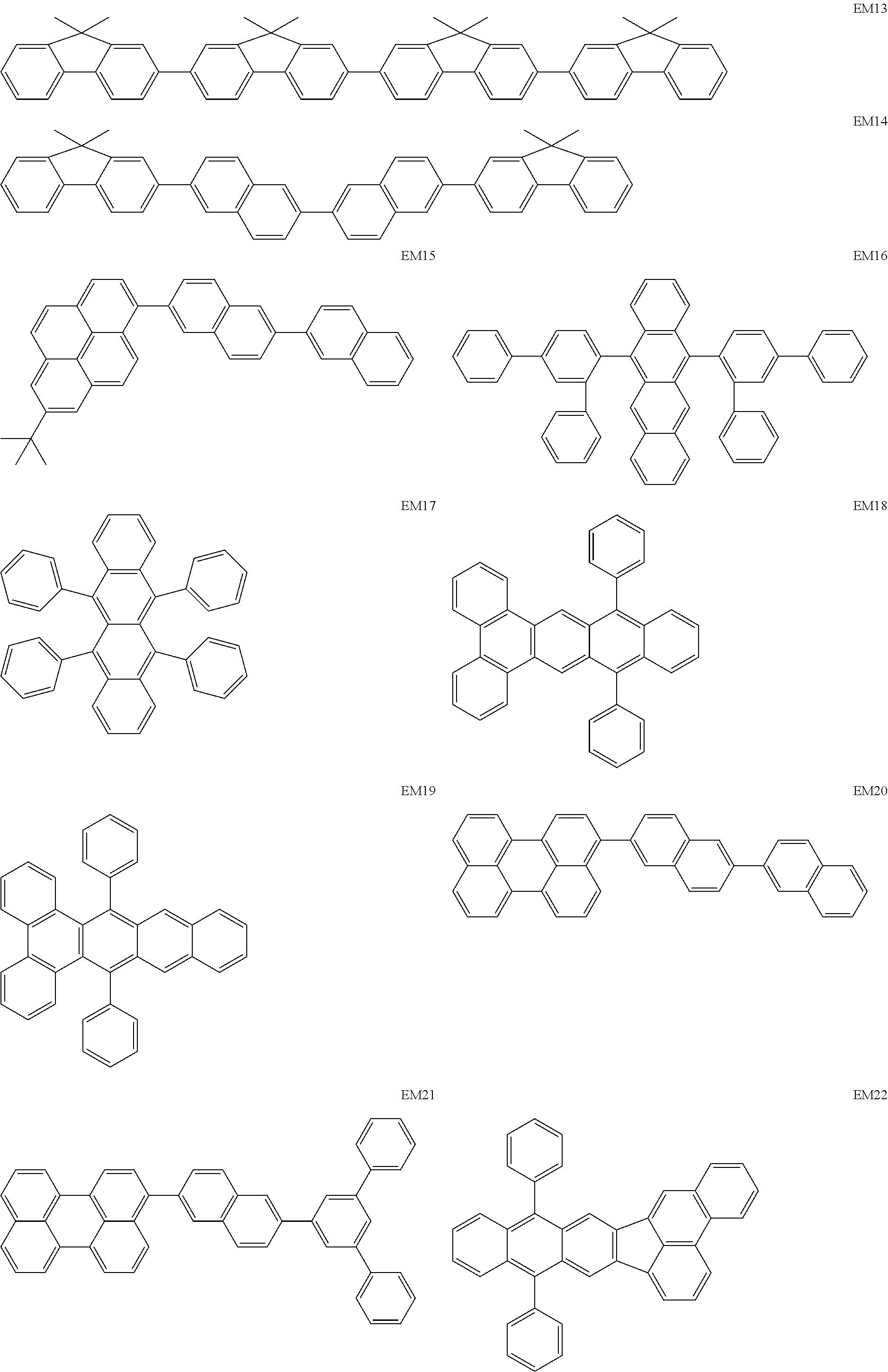

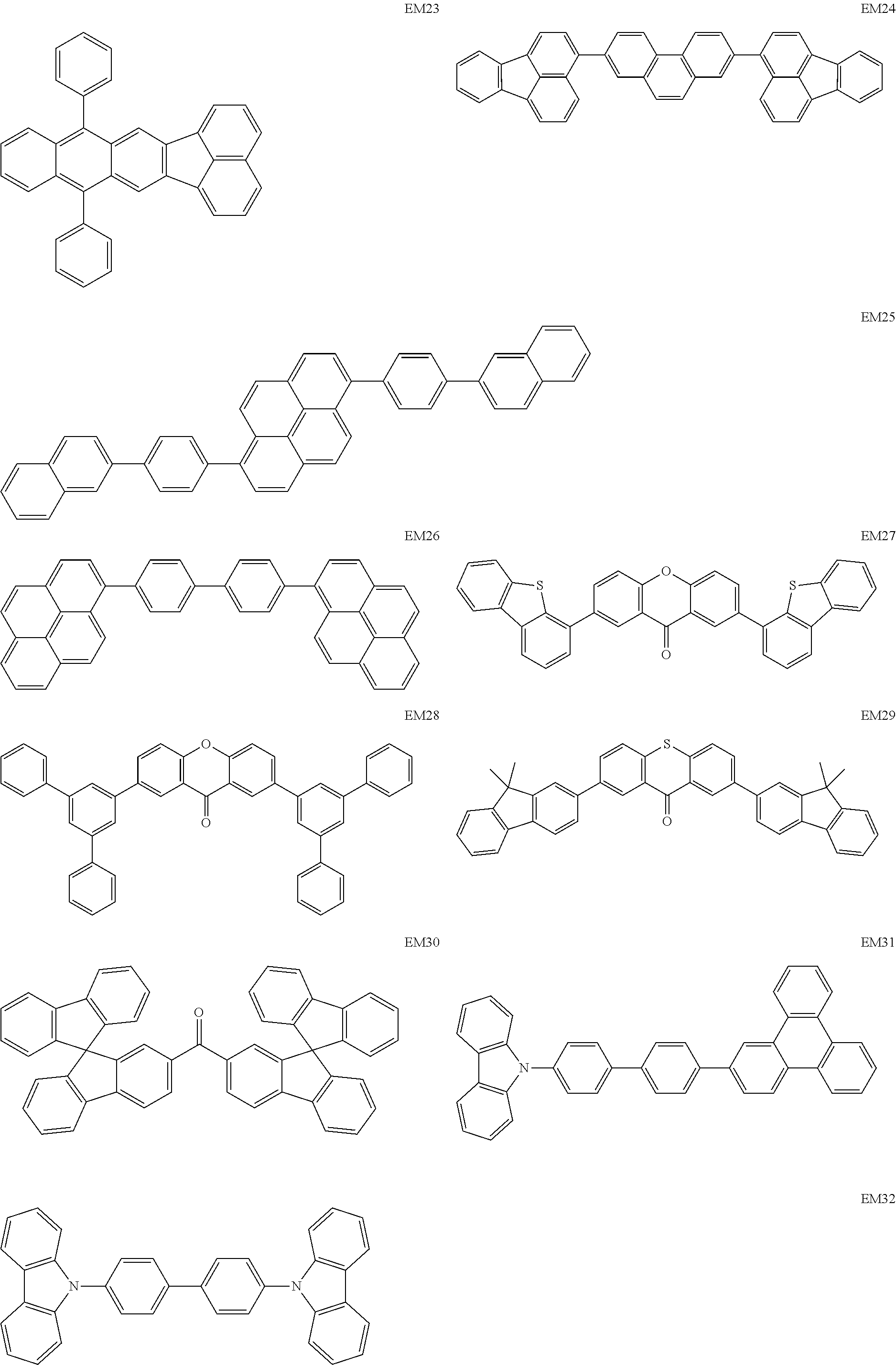

The host material may be a hydrocarbon compound. The hydrocarbon compound is a compound made of only carbon and hydrogen, and includes EM1 to EM12 and EM16 to EM27 in the compounds exemplified above. As the host material, a material that has, in a single bond that bonds an aryl group unit in its structure, no carbon-heteroatom bonds, like F3 in compound 1, is suitable from the viewpoint of stability.

The electron transport material can arbitrarily be selected from materials capable of transporting electrons injected from the cathode to the light emitting layer, and is selected in consideration of balance to the hole mobility of the hole transport material. Examples of the material having electron transport performance are an oxadiazole derivative, an oxazole derivative, a pyrazine derivative, a triazole derivative, a triazine derivative, a quinoline derivative, a quinoxaline derivative, a phenanthroline derivative, an organic aluminum complex, and condensed-ring compounds (for example, a fluorene derivative, a naphthalene derivative, a chrysene derivative, and an anthracene derivative). The above-described electron transport material is suitably used for the hole blocking layer as well.

Detailed examples of compounds used as the electron transport material will be shown below. The material is not limited to these.

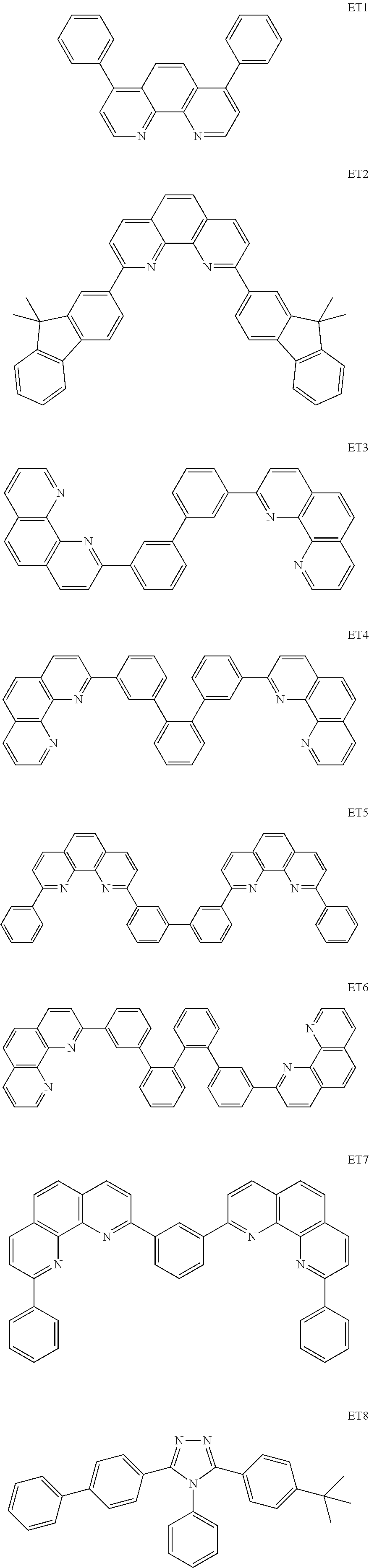

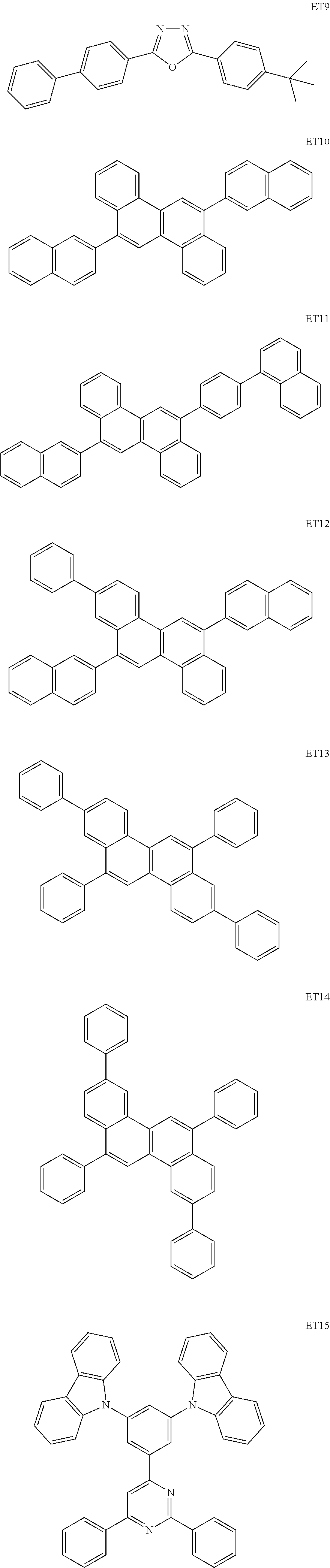

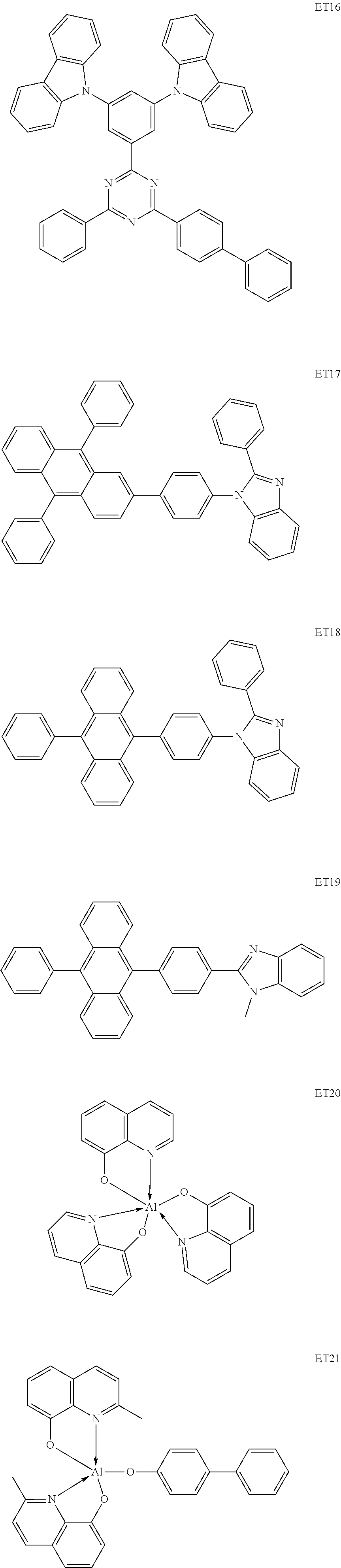

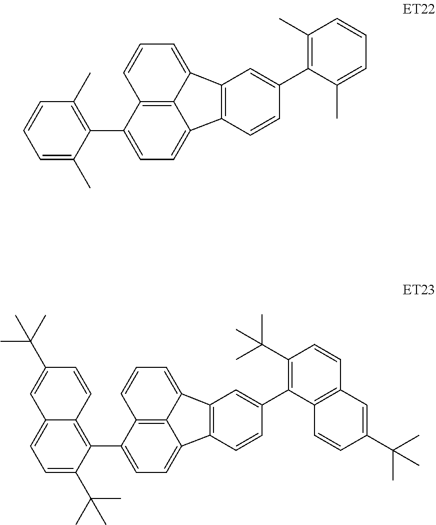

The electron injection material can arbitrarily be selected from materials capable of facilitating electron injection from the cathode, and is selected in consideration of balance to hole injection. The organic compound includes an n-type dopant and a reducible dopant. Examples are a compound containing an alkali metal such as lithium fluoride, a lithium complex such as a lithium-quinolinol complex, a benzo-imidazolidene derivative, an imidazolidene derivative, a fulvalene derivative, and an acridine derivative.

The electron injection material can also be used together with the above-described electron transport material.

### Configuration of Organic Light Emitting Element

The organic light emitting element is provided by forming an insulating layer, a first electrode, an organic compound layer, and a second electrode on a substrate. A protection layer, a color filter, a microlens, and the like may be provided on a cathode. If a color filter is provided, a planarizing layer may be provided between the protection layer and the color filter. The planarizing layer can be formed using acrylic resin or the like. The same applies to a case where a planarizing layer is provided between the color filter and the microlens.

### Substrate

Quartz, glass, a silicon wafer, a resin, a metal, or the like may be used as a substrate. Furthermore, a switching element such as a transistor, a wiring pattern, and the like may be provided on the substrate, and an insulating layer may be provided thereon. The insulating layer may be made of any material as long as a contact hole can be formed so that the wiring pattern can be formed between the first electrode and the substrate and insulation from the unconnected wiring pattern can be ensured. For example, a resin such as polyimide, silicon oxide, silicon nitride, or the like may be used for the insulating layer.

### Electrode

A pair of electrodes can be used as the electrodes. The pair of electrodes can be an anode and a cathode. If an electric field is applied in the direction in which the organic light emitting element emits light, the electrode having a high potential is the anode, and the other is the cathode. It can also be said that the electrode that supplies holes to the light emitting layer is the anode and the electrode that supplies electrons is the cathode.

As the constituent material of the anode, a material having a large work function may be selected. For example, a metal such as gold, platinum, silver, copper, nickel, palladium, cobalt, selenium, vanadium, or tungsten, a mixture containing some of them, an alloy obtained by combining some of them, or a metal oxide such as tin oxide, zinc oxide, indium oxide, indium tin oxide (ITO), or zinc indium oxide can be used. Furthermore, a conductive polymer such as polyaniline, polypyrrole, or polythiophene can also be used as the constituent material of the anode.

One of these electrode materials may be used singly, or two or more of them may be used in combination. The anode may be formed by a single layer or a plurality of layers.

If the electrode is used as a reflective electrode, for example, chromium, aluminum, silver, titanium, tungsten, molybdenum, an alloy thereof, a stacked layer thereof, or the like can be used. The above materials can function as a reflective film having no role as an electrode. If a transparent electrode is used as the electrode, an oxide transparent conductive layer made of indium tin oxide (ITO), indium zinc oxide, or the like can be used, but the present invention is not limited thereto. A photolithography technique can be used to form the electrode.

On the other hand, as the constituent material of the cathode, a material having a small work function may be selected. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used. One of these electrode materials may be used singly, or two or more of them may be used in combination. The cathode may have a single-layer structure or a multilayer structure. Silver may be used as the cathode. To suppress aggregation of silver, a silver alloy may be used. The ratio of the alloy is not limited as long as aggregation of silver can be suppressed. For example, the ratio between silver and another metal may be 1:1, 3:1, or the like.

The cathode may be a top emission element using an oxide conductive layer made of ITO or the like, or may be a bottom emission element using a reflective electrode made of aluminum (Al) or the like, and is not particularly limited. The method of forming the cathode is not particularly limited, but if direct current sputtering or alternating current sputtering is used, the good coverage is achieved for the film to be formed, and the resistance of the cathode can be lowered.

### Pixel Isolation Layer

A pixel isolation layer may be formed by a so-called silicon oxide, such as silicon nitride (SiN), silicon oxynitride (SiON), or silicon oxide (SiO), formed using a Chemical Vapor Deposition (CVD) method. To increase the resistance in the in-plane direction of the organic compound layer, the organic compound layer, especially the hole transport layer may be thinly deposited on the side wall of the pixel isolation layer. More specifically, the organic compound layer can be deposited so as to have a thin film thickness on the side wall by increasing the taper angle of the side wall of the pixel isolation layer or the film thickness of the pixel isolation layer to increase vignetting during vapor deposition.

On the other hand, the taper angle of the side wall of the pixel isolation layer or the film thickness of the pixel isolation layer can be adjusted to the extent that no space is formed in the protection layer formed on the pixel isolation layer. Since no space is formed in the protection layer, it is possible to reduce generation of defects in the protection layer. Since generation of defects in the protection layer is reduced, a decrease in reliability caused by generation of a dark spot or occurrence of a conductive failure of the second electrode can be reduced.

According to this embodiment, even if the taper angle of the side wall of the pixel isolation layer is not acute, it is possible to effectively suppress leakage of charges to an adjacent pixel. As a result of this consideration, it has been found that the taper angle of 60° (inclusive) to 90° (inclusive) can sufficiently reduce the occurrence of defects. The film thickness of the pixel isolation layer may be 10 nm (inclusive) to 150 nm (inclusive). A similar effect can be obtained in a configuration including only pixel electrodes without the pixel isolation layer. However, in this case, the film thickness of the pixel electrode is set to be equal to or smaller than half the film thickness of the organic layer or the end portion of the pixel electrode is formed to have a forward tapered shape of less than 60°. With this, short circuit of the organic light emitting element can be reduced.

Furthermore, in a case where the first electrode is the cathode and the second electrode is the anode, a high color gamut and low-voltage driving can be achieved by forming the electron transport material and charge transport layer and forming the light emitting layer on the charge transport layer.

### Organic Compound Layer

The organic compound layer may be formed by a single layer or a plurality of layers. If the organic compound layer includes a plurality of layers, the layers can be called a hole injection layer, a hole transport layer, an electron blocking layer, a light emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer may be arranged between the first and second electrodes, and may be arranged in contact with the first and second electrodes. If a plurality of light emitting layers are provided, a charge generation portion may be arranged between the first light emitting layer and the second light emitting layer. The charge generation portion may contain an organic compound with a lowest unoccupied molecular orbital energy (LUMO) of −5.0 eV or less. The same applies to a case where a charge generation portion is provided between the second light emitting layer and the third light emitting layer.

### Protection Layer

A protection layer may be provided on the cathode. For example, by adhering glass provided with a moisture absorbing agent on the cathode, permeation of water or the like into the organic compound layer can be suppressed and occurrence of display defects can be suppressed. Furthermore, as another embodiment, a passivation layer made of silicon nitride or the like may be provided on the cathode to suppress permeation of water or the like into the organic compound layer. For example, the protection layer can be formed by forming the cathode, transferring it to another chamber without breaking the vacuum, and forming silicon nitride having a thickness of 2 μm by the CVD method. The protection layer may be provided using an atomic layer deposition (ALD) method after deposition of the protection layer using the CVD method. The material of the protection layer by the ALD method is not limited but can be silicon nitride, silicon oxide, aluminum oxide, or the like. Silicon nitride may further be formed by the CVD method on the protection layer formed by the ALD method. The protection layer formed by the ALD method may have a film thickness smaller than that of the protection layer formed by the CVD method. More specifically, the film thickness of the protection layer formed by the ALD method may be 50% or less, or 10% or less of that of the protection layer formed by the CVD method.

### Color Filter

A color filter may be provided on the protection layer. For example, a color filter considering the size of the organic light emitting element may be provided on another substrate, and the substrate with the color filter formed thereon may be bonded to the substrate with the organic light emitting element provided thereon. Alternatively, for example, a color filter may be patterned on the above-described protection layer using a photolithography technique. The color filter may be formed from a polymeric material.

### Planarizing Layer

A planarizing layer may be arranged between the color filter and the protection layer. The planarizing layer is provided to reduce unevenness of the layer below the planarizing layer. The planarizing layer may be called a material resin layer without limiting the purpose of the layer. The planarizing layer may be formed from an organic compound, and may be made of a low-molecular material or a polymeric material. In consideration of reduction of unevenness, a polymeric organic compound may be used for the planarizing layer.

The planarizing layers may be provided above and below the color filter. In that case, the same or different constituent materials may be used for these planarizing layers. More specifically, examples of the material of the planarizing layer include polyvinyl carbazole resin, polycarbonate resin, polyester resin, ABS resin, acrylic resin, polyimide resin, phenol resin, epoxy resin, silicone resin, and urea resin.

### Microlens

The organic light emitting device may include an optical member such as a microlens on the light emission side. The microlens can be made of acrylic resin, epoxy resin, or the like. The microlens can aim to increase the amount of light extracted from the organic light emitting device and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. That is, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface opposite to the first surface. The second surface can be arranged on the functional layer (light emitting layer) side of the first surface. For this configuration, the microlens needs to be formed on the light emitting device. If the functional layer is an organic layer, a process which produces high temperature in the manufacturing step of the microlens may be avoided. In addition, if it is configured to arrange the second surface on the functional layer side of the first surface, all the glass transition temperatures of an organic compound forming the organic layer may be 100° C. or more. For example, 130° C. or more is suitable.

### Counter Substrate

A counter substrate may be arranged on the planarizing layer. The counter substrate is called a counter substrate because it is provided at a position corresponding to the above-described substrate. The constituent material of the counter substrate can be the same as that of the above-described substrate. If the above-described substrate is the first substrate, the counter substrate can be the second substrate.

### Organic Layer

The organic compound layer (hole injection layer, hole transport layer, electron blocking layer, light emitting layer, hole blocking layer, electron transport layer, electron injection layer, and the like) forming the organic light emitting element according to an embodiment of the present disclosure may be formed by the method to be described below.

The organic compound layer forming the organic light emitting element according to the embodiment of the present disclosure can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as needed.

### Pixel Circuit

The light emitting device can include a pixel circuit connected to the light emitting element. The pixel circuit may be an active matrix circuit that individually controls light emission of the first and second light emitting elements. The active matrix circuit may be a voltage or current programing circuit. A driving circuit includes a pixel circuit for each pixel. The pixel circuit can include a light emitting element, a transistor for controlling light emission luminance of the light emitting element, a transistor for controlling a light emission timing, a capacitor for holding the gate voltage of the transistor for controlling the light emission luminance, and a transistor for connection to GND without intervention of the light emitting element.

The light emitting device includes a display region and a peripheral region arranged around the display region. The light emitting device includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light emitting element such as the first light emitting element.

### Pixel

The organic light emitting device includes a plurality of pixels. Each pixel includes sub-pixels that emit light components of different colors. The sub-pixels may include, for example, R, G, and B emission colors, respectively.

In each pixel, a region also called a pixel opening emits light. The pixel opening can have a size of 5 μm (inclusive) to 15 μm (inclusive). More specifically, the pixel opening can have a size of 11 μm, 9.5 μm, 7.4 μm, 6.4 μm, or the like.

A distance between the sub-pixels can be 10 μm or less, and can be, more specifically, 8 μm, 7.4 μm, or 6.4 μm.

The pixels can have a known arrangement form in a plan view. For example, the pixels may have a stripe arrangement, a delta arrangement, a pentile arrangement, or a Bayer arrangement. The shape of each sub-pixel in a plan view may be any known shape. For example, a quadrangle such as a rectangle or a rhombus, a hexagon, or the like may be possible. A shape which is not strictly the right shape but is close to a quadrangle is encompassed in “quadrangle”, as a matter of course. The shape of the sub-pixel and the pixel arrangement can be used in combination.

### Application of Organic Light Emitting Element of Embodiment of Present Disclosure

The organic light emitting element according to an embodiment of the present disclosure can be used as a constituent member of a display device or an illumination device. In addition, the organic light emitting element is applicable to the exposure light source of an electrophotographic image forming device, the backlight of a liquid crystal display device, a light emitting device including a color filter in a white light source, and the like.

The display device may be an image information processing device that includes an image input unit for inputting image information from an area CCD, a linear CCD, a memory card, or the like, and an information processing unit for processing the input information, and displays the input image on a display unit.

In addition, a display unit included in an image capturing device or an inkjet printer can have a touch panel function. The driving type of the touch panel function may be an infrared type, a capacitance type, a resistive film type, or an electromagnetic induction type, and is not particularly limited. The display device may be used for the display unit of a multifunction printer.

More details will be described next with reference to the accompanying drawings. FIG. 15A shows an example of the pixel arranged in the light emitting device 100. The pixel includes sub-pixels 810 (light emitting elements 210). The sub-pixels are divided into sub-pixels 810R, 810G, and 810B by light emission color. The light emission colors may be discriminated by the wavelengths of light components emitted from the light emitting layers, or light emitted from each sub-pixel may be selectively transmitted or undergo color conversion by a color filter or the like. Each sub-pixel includes a reflective electrode 802 as the first electrode on an interlayer insulating layer 801, an insulating layer 803 covering the end of the reflective electrode 802, an organic compound layer 804 covering the first electrode and the insulating layer, a transparent electrode 805 as the second electrode, a protection layer 806, and a color filter 807.

The interlayer insulating layer 801 can include a transistor and a capacitive element arranged in the interlayer insulating layer 801 or a layer below it. The transistor and the first electrode can electrically be connected via a contact hole (not shown) or the like.

The insulating layer 803 can also be called a bank or a pixel isolation film. The insulating layer 803 covers the end of the first electrode, and is arranged to surround the first electrode. A portion of the first electrode where no insulating layer 803 is arranged is in contact with the organic compound layer 804 to form a light emitting region.

The organic compound layer 804 includes a hole injection layer 841, a hole transport layer 842, a first light emitting layer 843, a second light emitting layer 844, and an electron transport layer 845.

The second electrode may be a transparent electrode, a reflective electrode, or a semi-transmissive electrode.

The protection layer 806 suppresses permeation of water into the organic compound layer. The protection layer is shown as a single layer but may include a plurality of layers. Each layer can be an inorganic compound layer or an organic compound layer.

The color filter 807 is divided into color filters 807R, 807G, and 807B by colors. The color filters can be formed on a planarizing film (not shown). A resin protection layer (not shown) may be arranged on the color filters. The color filters can be formed on the protection layer 806. Alternatively, the color filters can be provided on the counter substrate such as a glass substrate, and then the substrate may be bonded.

The display device 800 (corresponding to the above-described light emitting device 100) shown in FIG. 15B is provided with an organic light emitting element 826 as an example of a light emitting element and a TFT 818 as an example of a transistor. A substrate 811 of glass, silicon, or the like is provided and an insulating layer 812 is provided on the substrate 811. The active element such as the TFT 818 is arranged on the insulating layer, and a gate electrode 813, a gate insulating film 814, and a semiconductor layer 815 of the active element are arranged. The TFT 818 further includes the semiconductor layer 815, a drain electrode 816, and a source electrode 817. An insulating film 819 is provided on the TFT 818. The source electrode 817 and an anode 821 forming the organic light emitting element 826 are connected via a contact hole 820 formed in the insulating film.

A method of electrically connecting the electrodes (anode and cathode) included in the organic light emitting element 826 and the electrodes (source electrode and drain electrode) included in the TFT is not limited to that shown in FIG. 15B. That is, one of the anode and cathode and one of the source electrode and drain electrode of the TFT are electrically connected. The TFT indicates a thin-film transistor.

In the display device 800 shown in FIG. 15B, an organic compound layer is illustrated as one layer. However, an organic compound layer 822 may include a plurality of layers. A first protection layer 824 and a second protection layer 825 are provided on a cathode 823 to suppress deterioration of the organic light emitting element.

A transistor is used as a switching element in the display device 800 shown in FIG. 15B, but another switching element may be used instead.

The transistor used in the display device 800 shown in FIG. 15B is not limited to a transistor using a single-crystal silicon wafer, and may be a thin-film transistor including an active layer on an insulating surface of a substrate. Examples of the active layer include single-crystal silicon, amorphous silicon, non-single-crystal silicon such as microcrystalline silicon, and a non-single-crystal oxide semiconductor such as indium zinc oxide and indium gallium zinc oxide. Note that a thin-film transistor is also called a TFT element.

The transistor included in the display device 800 shown in FIG. 15B may be formed in the substrate such as a silicon substrate. Forming the transistor in the substrate means forming the transistor by processing the substrate such as a silicon substrate. That is, when the transistor is included in the substrate, it can be considered that the substrate and the transistor are formed integrally.

The light emission luminance of the organic light emitting element according to this embodiment can be controlled by the TFT which is an example of a switching element, and the plurality of organic light emitting elements can be provided in a plane to display an image with the light emission luminances of the respective elements. Here, the switching element according to this embodiment is not limited to the TFT, and may be a transistor formed from low-temperature polysilicon or an active matrix driver formed on the substrate such as a silicon substrate. The term “on the substrate” may mean “in the substrate”. Whether to provide a transistor in the substrate or use a TFT is selected based on the size of the display unit. For example, if the size is about 0.5 inch, the organic light emitting element may be provided on the silicon substrate.

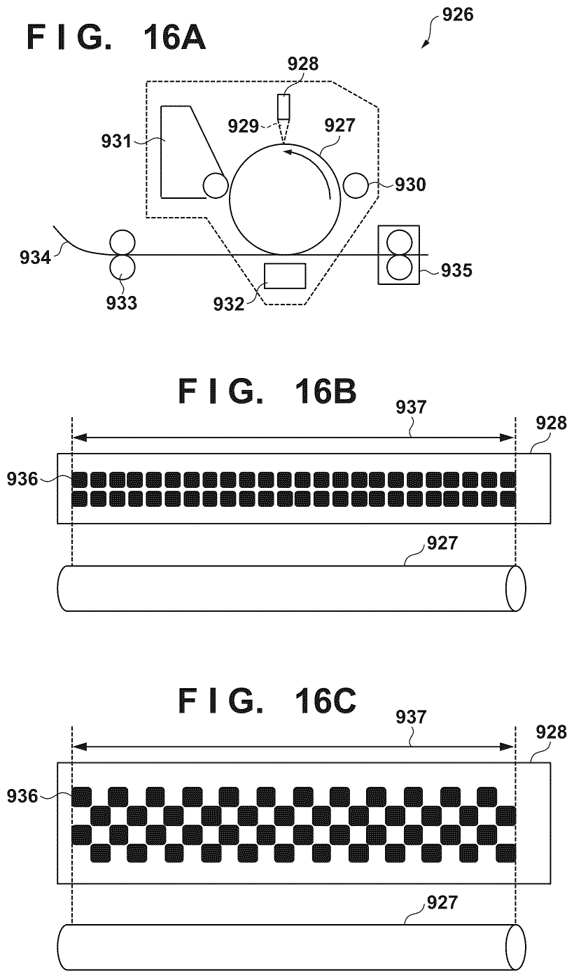

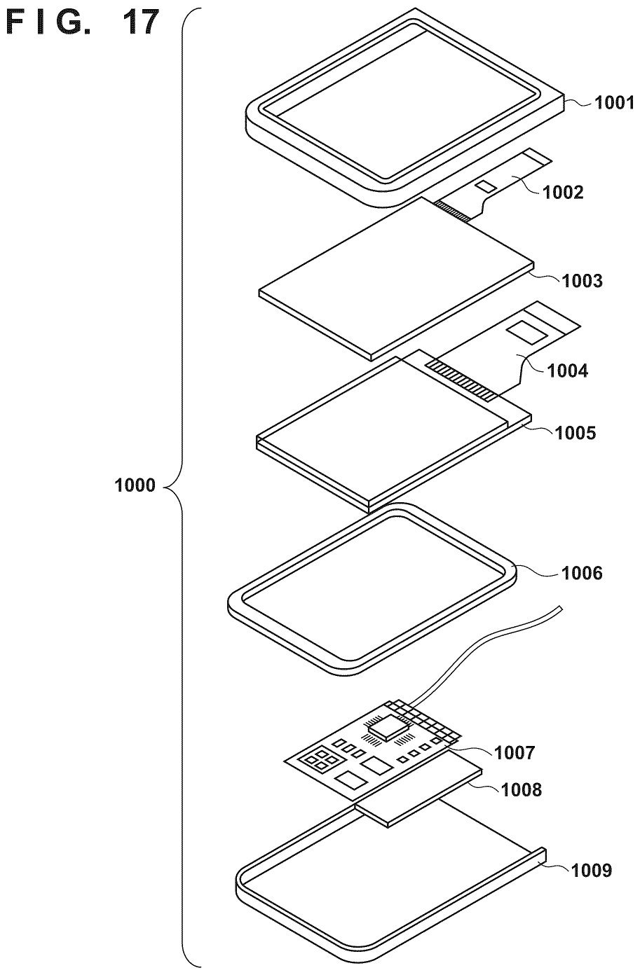

FIGS. 16A to 16C are schematic views showing an example of an image forming device using the light emitting device 100 according to this embodiment. An image forming device 926 shown in FIG. 16A includes a photosensitive member 927, an exposure light source 928, a developing unit 931, a charging unit 930, a transfer device 932, a conveyance unit 933 (a conveyance roller in the arrangement shown in FIG. 16A), and a fixing device 935.

Light 929 is emitted from the exposure light source 928, and an electrostatic latent image is formed on the surface of the photosensitive member 927. The light emitting device 100 can be applied to the exposure light source 928. The developing unit 931 can function as a developing device that includes a toner or the like as a developing agent and applies the developing agent to the exposed photosensitive member 927. The charging unit 930 charges the photosensitive member 927. The transfer device 932 transfers the developed image to a print medium 934. The conveyance unit 933 conveys the print medium 934. The print medium 934 can be, for example, paper, a film, or the like. The fixing device 935 fixes the image formed on the print medium.

Each of FIGS. 16B and 16C is a schematic view showing a form in which a plurality of light emitting units 936 are arranged in the exposure light source 928 along the longitudinal direction of a long substrate. The light emitting device 100 can be applied to each of the light emitting units 936. That is, a plurality of the pixels (light emitting elements 210) are arranged along the longitudinal direction of the substrate. A direction 937 is a direction parallel to the axis of the photosensitive member 927. This column direction matches the direction of the axis upon rotating the photosensitive member 927. This direction 937 can also be referred to as the long-axis direction of the photosensitive member 927.

FIG. 16B shows a form in which the light emitting units 936 are arranged along the long-axis direction of the photosensitive member 927. FIG. 16C shows a form, which is a modification of the arrangement of the light emitting units 936 shown in FIG. 16B, in which the light emitting units 936 are arranged in the column direction alternately between the first column and the second column. The light emitting units 936 are arranged at different positions in the row direction between the first column and the second column. In the first column, the plurality of light emitting units 936 are arranged apart from each other. In the second column, the light emitting unit 936 is arranged at the position corresponding to the space between the light emitting units 936 in the first column. Furthermore, in the row direction, the plurality of light emitting units 936 are arranged apart from each other. The arrangement of the light emitting units 936 shown in FIG. 16C can be referred to as, for example, an arrangement in a grid pattern, an arrangement in a staggered pattern, or an arrangement in a checkered pattern.

FIG. 17 is a schematic view showing an example of the display device using the light emitting device 100 according to this embodiment. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. A control circuit including a logic circuit formed from transistors and the like is arranged on the circuit board 1007. The battery 1008 is unnecessary if the display device 1000 is not a portable apparatus. Even when the display device 1000 is a portable apparatus, the battery 1008 need not be provided at this position. The light emitting device 100 can be applied to the display panel 1005. The pixels (light emitting elements 210) arranged in the light emitting device 100 functioning as the display panel 1005 are connected to the control circuit arranged on the circuit board 1007 and operate.

The display device 1000 shown in FIG. 17 can be used for a display unit of a photoelectric conversion device (also referred to as an image capturing device) including an optical unit having a plurality of lenses, and an image sensor for receiving light having passed through the optical unit and photoelectrically converting the light into an electric signal. The photoelectric conversion device can include a display unit for displaying information acquired by the image sensor. In addition, the display unit can be either a display unit exposed outside the photoelectric conversion device, or a display unit arranged in the finder. The photoelectric conversion device can be a digital camera or a digital video camera.

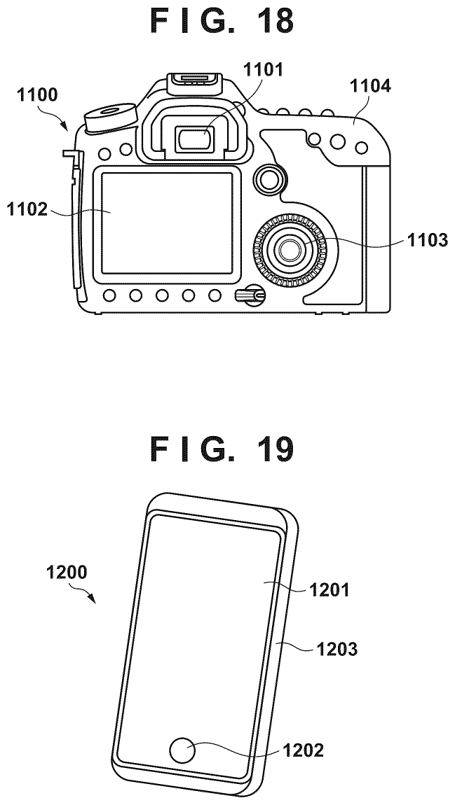

FIG. 18 is a schematic view showing an example of the photoelectric conversion device using the light emitting device 100 according to this embodiment. A photoelectric conversion device 1100 can include a viewfinder 1101, a rear display 1102, an operation unit 1103, and a housing 1104. The photoelectric conversion device 1100 can also be called an image capturing device. The light emitting device 100 according to this embodiment can be applied to the viewfinder 1101 or the rear display 1102 as a display unit. In this case, the light emitting device 100 can display not only an image to be captured but also environment information, image capturing instructions, and the like. Examples of the environment information are the intensity and direction of external light, the moving velocity of an object, and the possibility that an object is covered with an obstacle.

Since the timing suitable for image capturing is a very short time in many cases, it is better to display the information as soon as possible. Therefore, the light emitting device 100 in which the pixel (light emitting element 210) including the light emitting element using the organic light emitting material such as an organic EL element is arranged may be used for the viewfinder 1101 or the rear display 1102. This is so because the organic light emitting material has a high response speed. The light emitting device 100 using the organic light emitting material can be used for the devices that require a high display speed more suitably than for the liquid crystal display device.

The photoelectric conversion device 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also automatically be performed.

The light emitting device 100 may be applied to a display unit of an electronic apparatus. At this time, the display unit can have both a display function and an operation function. Examples of the portable terminal are a portable phone such as a smartphone, a tablet, and a head mounted display.

FIG. 19 is a schematic view showing an example of an electronic apparatus using the light emitting device 100 according to this embodiment. An electronic apparatus 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable apparatus including the communication unit can also be regarded as a communication apparatus. The light emitting device 100 according to this embodiment can be applied to the display unit 1201.

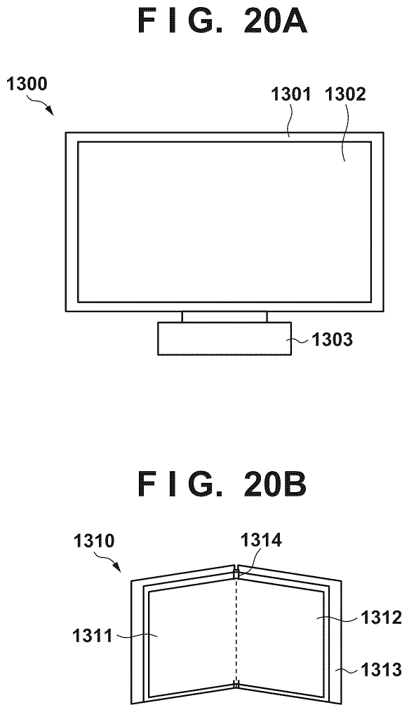

FIGS. 20A and 20B are schematic views showing examples of the display device using the light emitting device 100 according to this embodiment. FIG. 20A shows a display device such as a television monitor or a PC monitor. A display device 1300 includes a frame 1301 and a display unit 1302. The light emitting device 100 according to this embodiment can be applied to the display unit 1302. The display device 1300 can include a base 1303 that supports the frame 1301 and the display unit 1302. The base 1303 is not limited to the form shown in FIG. 20A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 20B is a schematic view showing another example of the display device using the light emitting device 100 according to this embodiment. A display device 1310 shown in FIG. 20B can be folded, and is a so-called foldable display device. The display device 1310 includes a first display unit 1311, a second display unit 1312, a housing 1313, and a bending point 1314. The light emitting device 100 according to this embodiment can be applied to each of the first display unit 1311 and the second display unit 1312. The first display unit 1311 and the second display unit 1312 can also be one seamless display device. The first display unit 1311 and the second display unit 1312 can be divided by the bending point. The first display unit 1311 and the second display unit 1312 can display different images, and can also display one image together.

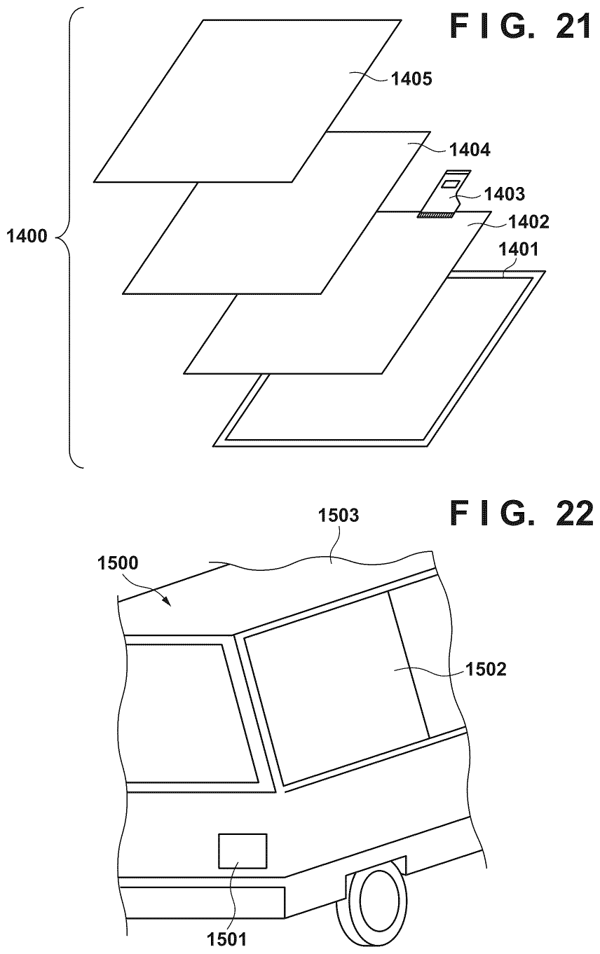

FIG. 21 is a schematic view showing an example of the illumination device using the light emitting device 100 according to this embodiment. An illumination device 1400 can include a housing 1401, a light source 1402, a circuit board 1403, an optical film 1404, and a light diffusing unit 1405. The light emitting device 100 according to this embodiment can be applied to the light source 1402. The optical film 1404 can be a filter that improves the color rendering of the light source. When performing lighting-up or the like, the light diffusing unit 1405 can throw the light of the light source over a broad range by effectively diffusing the light. The illumination device can also include a cover on the outermost portion, as needed. The illumination device 1400 can include both or one of the optical film 1404 and the light diffusing unit 1405.

The illumination device 1400 is, for example, a device for illuminating the interior of the room. The illumination device 1400 can emit white light, natural white light, or light of any color from blue to red. The illumination device 1400 can also include a light control circuit for controlling these light components. The illumination device 1400 can also include a power supply circuit connected to the light emitting device 100 functioning as the light source 1402. The power supply circuit is a circuit for converting an AC voltage into a DC voltage. White has a color temperature of 4,200 K, and natural white has a color temperature of 5,000 K. The illumination device 1400 may also include a color filter. In addition, the illumination device 1400 can include a heat radiation unit. The heat radiation unit radiates the internal heat of the device to the outside of the device, and examples are a metal having a high specific heat and liquid silicon.

FIG. 22 is a schematic view of an automobile having a taillight as an example of a vehicle lighting appliance using the light emitting device 100 according to this embodiment. An automobile 1500 has a taillight 1501, and can have a form in which the taillight 1501 is turned on when performing a braking operation or the like. The light emitting device 100 according to this embodiment can be used as a headlight serving as a vehicle lighting appliance. The automobile is an example of a moving body, and the moving body may be a ship, a drone, an aircraft, a railroad car, an industrial robot, or the like. The moving body may include a main body and a lighting appliance provided in the main body. The lighting appliance may be used to make a notification of the current position of the main body.

The light emitting device 100 according to this embodiment can be applied to the taillight 1501. The taillight 1501 can include a protection member for protecting the light emitting device 100 functioning as the taillight 1501. The material of the protection member is not limited as long as the material is a transparent material with a strength that is high to some extent, and an example is polycarbonate. The protection member may be made of a material obtained by mixing a furandicarboxylic acid derivative, an acrylonitrile derivative, or the like in polycarbonate.

The automobile 1500 can include a vehicle body 1503, and a window 1502 attached to the vehicle body 1503. This window can be a window for checking the front and back of the automobile, and can also be a transparent display such as a head-up display. For this transparent display, the light emitting device 100 according to this embodiment may be used. In this case, the constituent materials of the electrodes and the like of the light emitting device 100 are formed by transparent members.

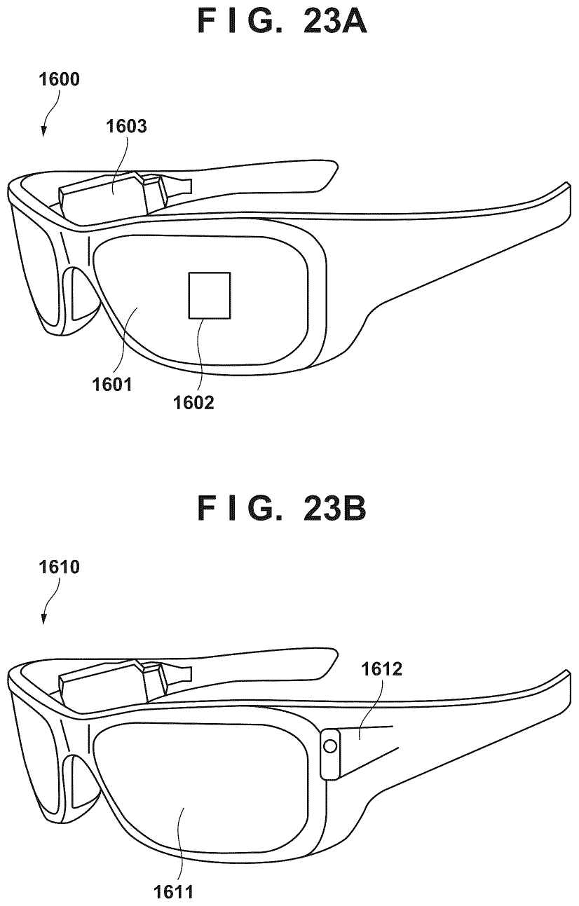

Further application examples of the light emitting device 100 according to this embodiment will be described with reference to FIGS. 23A and 23B. The light emitting device 100 can be applied to a system that can be worn as a wearable device such as smartglasses, a Head Mounted Display (TIMID), or a smart contact lens. An image capturing display device used for such application examples includes an image capturing device capable of photoelectrically converting visible light and a light emitting device capable of emitting visible light.

Glasses 1600 (smartglasses) according to one application example will be described with reference to FIG. 23A. An image capturing device 1602 such as a CMOS sensor or an SPAD is provided on the surface side of a lens 1601 of the glasses 1600. In addition, the light emitting device 100 according to this embodiment is provided on the back surface side of the lens 1601.

The glasses 1600 further include a control device 1603. The control device 1603 functions as a power supply that supplies electric power to the image capturing device 1602 and the light emitting device 100 according to each embodiment. In addition, the control device 1603 controls the operations of the image capturing device 1602 and the light emitting device 100. An optical system configured to condense light to the image capturing device 1602 is formed on the lens 1601.

Glasses 1610 (smartglasses) according to one application example will be described with reference to FIG. 23B. The glasses 1610 include a control device 1612, and an image capturing device corresponding to the image capturing device 1602 and the light emitting device 100 are mounted on the control device 1612. The image capturing device in the control device 1612 and an optical system configured to project light emitted from the light emitting device 100 are formed in a lens 1611, and an image is projected to the lens 1611. The control device 1612 functions as a power supply that supplies electric power to the image capturing device and the light emitting device 100, and controls the operations of the image capturing device and the light emitting device 100. The control device 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting device 100 according to the embodiment of the present disclosure can include an image capturing device including a light receiving element, and control a displayed image based on the line-of-sight information of the user from the image capturing device.

More specifically, the light emitting device 100 decides a first visual field region at which the user is gazing and a second visual field region other than the first visual field region based on the line-of-sight information. The first visual field region and the second visual field region may be decided by the control device of the light emitting device 100, or those decided by an external control device may be received. In the display region of the light emitting device 100, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the light emitting device 100, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting device 100, the image capturing device, or an external device. If the external device holds the AI program, it is transmitted to the light emitting device 100 via communication.

When performing display control based on line-of-sight detection, smartglasses further including an image capturing device configured to capture the outside can be applied. The smartglasses can display captured outside information in real time.

The disclosure of the present specification includes the following manufacturing method of a light emitting device.

### (Method 1)

There is provided a manufacturing method of a light emitting device that includes a plurality of light emitting elements arranged on a main surface of a substrate, the method including
forming an insulating layer including a concave portion on the main surface,
embedding a first electrode in the concave portion,
forming a groove in a side wall of the concave portion,
forming an organic layer including a light emitting layer and an organic functional layer arranged between the light emitting layer and the first electrode so as to cover the insulating layer and the first electrode, and
forming a second electrode so as to cover the organic layer,
wherein the groove is arranged in a portion of the side wall farther from the main surface than a surface of the first electrode, and
in an orthogonal projection to the main surface, a portion of the insulating layer farther from the main surface than the surface of the first electrode does not overlap the first electrode.

### (Method 2)

In the manufacturing method according to Method 1,
the forming the insulating layer includes forming a first insulating layer, forming a second insulating layer so as to cover the first insulating layer, and forming a third insulating layer so as to cover the second insulating layer, and
the second insulating layer contains a material different from materials for the first insulating layer and the third insulating layer.

### (Method 3)

In the manufacturing method according to Method 1, the forming the groove includes selectively etching the second insulating layer with respect to the first insulating layer and the third insulating layer.

### (Method 4)

In the manufacturing method according to Method 1,
the forming the groove includes performing chemical etching using CF₄ gas, and
an etching rate of the second insulating layer is higher than etching rates of the first insulating layer and the third insulating layer in chemical etching using CF₄ gas.

### (Method 5)

In the manufacturing method according to Method 1,
the embedding the first electrode includes
forming a conductive material on the insulating layer,
planarizing a surface of the conductive material, and
selectively etching the conductive material with respect to the insulating layer.

### (Method 6)

In the manufacturing method according to Method 5,
the groove is formed during the selectively etching the conductive material or after the selectively etching the conductive material.

### (Method 7)

In the manufacturing method according to Method 1, the forming the groove is performed before the embedding the first electrode.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-041588, filed Mar. 15, 2024, which is hereby incorporated by reference herein in its entirety.

What is claimed is:

1. Alight emitting device comprising a plurality of light emitting elements arranged on a main surface of a substrate, wherein
each of the plurality of light emitting elements includes:
a first electrode arranged in a concave portion provided in an insulating layer arranged on the main surface;
an organic layer arranged so as to cover the insulating layer and the first electrode, and including a light emitting layer and an organic functional layer arranged between the light emitting layer and the first electrode; and
a second electrode arranged so as to cover the organic layer,
a groove is provided in a portion of a side wall of the concave portion farther from the main surface than a surface of the first electrode, and
a portion of the insulating layer farther from the main surface than the surface of the first electrode does not overlap the first electrode in an orthogonal projection to the main surface.

2. The device according to claim 1, wherein in the orthogonal projection to the main surface, the groove is arranged so as to surround the first electrode.

3. The device according to claim 1, wherein the organic functional layer is divided at the groove, or includes a portion covering the groove and having a film thickness smaller than a film thickness of an adjacent portion adjacent to the portion covering the groove.

4. The device according to claim 1, wherein
the insulating layer includes a first insulating layer, a second insulating layer arranged between the first insulating layer and the main surface, and a third insulating layer arranged between the second insulating layer and the main surface, and
in the side wall, the groove is formed by the second insulating layer recessed more than the first insulating layer and the third insulating layer in a direction parallel to the main surface.

5. The device according to claim 4, wherein the second insulating layer contains a material different from materials for the first insulating layer and the third insulating layer.

6. The device according to claim 4, wherein the second insulating layer contains a material having a higher etching rate than the first insulating layer and the third insulating layer in chemical etching using CF₄ gas.

7. The device according to claim 4, wherein a length between a surface of the first electrode and the second insulating layer in a normal direction of the main surface is larger than a length of a portion of the organic functional layer in contact with the first electrode in the normal direction.

8. The device according to claim 4, wherein a length of the first insulating layer in a normal direction of the main surface is larger than a length of a portion of the organic functional layer in contact with the first electrode in the normal direction.

9. The device according to claim 4, wherein a length of the second insulating layer in a normal direction of the main surface is larger than a length of a portion of the organic functional layer in contact with the first electrode in the normal direction.

10. The device according to claim 4, wherein a length of the first insulating layer protruding from the second insulating layer in the side wall is larger than a length of a portion of the organic functional layer in contact with the first electrode in a normal direction of the main surface.

11. The device according to claim 1, wherein the organic functional layer includes at least one of a hole injection layer and a hole transport layer.

12. The device according to claim 1, wherein a length, in a normal direction of the main surface, between a surface of the first electrode and a portion of the side wall farthest from the main surface is smaller than a length, in the normal direction, of a portion of the organic layer excluding the organic functional layer arranged on the first electrode.

13. The device according to claim 1, wherein a portion of the side wall excluding the groove has an inclination not less than 50 with respect to a direction parallel to the main surface.

14. The device according to claim 1, wherein the first electrode includes a first conductive layer, a second conductive layer arranged between the first conductive layer and the main surface, and a third conductive layer arranged between the second conductive layer and the main surface.

15. The device according to claim 14, wherein
the plurality of light emitting elements include a first light emitting element and a second light emitting element, and
a length of the first conductive layer arranged in the first light emitting element in a normal direction of the main surface is different from a length of the first conductive layer arranged in the second light emitting element in the normal direction.

16. The device according to claim 14, wherein
the first electrode further includes a fourth insulating layer arranged between the first conductive layer and the second conductive layer, and
the first conductive layer and the second conductive layer are electrically connected by a conductor arranged in a through hole provided in the fourth insulating layer.

17. The device according to claim 16, wherein
the plurality of light emitting elements include a third light emitting element and a fourth light emitting element, and
a length of the fourth insulating layer arranged in the third light emitting element in a normal direction of the main surface is different from a length of the fourth insulating layer arranged in the fourth light emitting element in the normal direction.

18. The device according to claim 1, wherein a surface of the first electrode has a concave shape with a central portion recessed more than the other portion in a direction of the main surface.

19. The device according to claim 1, wherein the groove is depressed from a surface of the side wall in a direction parallel to the main surface.

20. A display device comprising the light emitting device according to claim 1, and a control circuit connected to the light emitting device.

21. A photoelectric conversion device comprising an optical unit including a plurality of lenses, an image sensor configured to receive light having passed through the optical unit, and a display unit configured to display an image,
wherein the display unit displays an image captured by the image sensor, and includes the light emitting device according to claim 1.

22. An electronic apparatus comprising a housing provided with a display unit, and a communication unit provided in the housing and configured to perform external communication,
wherein the display unit includes the light emitting device according to claim 1.

23. An illumination device comprising a light source, and at least one of a light diffusing unit and an optical film,
wherein the light source includes the light emitting device according to claim 1.

24. A moving body comprising a main body, and a lighting appliance provided in the main body,
wherein the lighting appliance includes the light emitting device according to claim 1.
